(19) United States
(12) Patent Application Publication
(10) Pub. No.: US 2026/0136784 A1
(43) Pub. Date: May 14, 2026

(54) DISPLAY PANEL AND DISPLAY DEVICE

(71) Applicant: BOE Technology Group Co., Ltd., Beijing (CN)

(72) Inventors: Hao ZHANG, Beijing (CN); Bingwei WANG, Beijing (CN); Chunyan XIE, Beijing (CN); Hejin WANG, Beijing (CN); Zunqing SONG, Beijing (CN)

(21) Appl. No.: 18/853,093

(22) PCT Filed: Feb. 6, 2024
(86) PCT No.: PCT/CN2024/076392

§ 371 Date: Sep. 30, 2024

(30) Foreign Application Priority Data
Mar. 29, 2023 (CN) 202310322958.1

(51) Int. Cl. H10K 59/131; H10K 59/121; H10K 59/124; H10K 59/80

(52) U.S. Cl. CPC H10K 59/131; H10K 59/1213; H10K 59/1216; H10K 59/124; H10K 59/873

(57) ABSTRACT

A display panel and a display device. The display panel includes a circuit layer including a group of insulating layers and a group of conductive layers; where the circuit layer is divided into a group of pixel circuits in the display region and a group of peripheral driving circuits in the peripheral region; orthographic projections of conductive layers and insulating layers included in the peripheral driving circuit on the substrate overlap with the island region and the bridge region; the orthographic projections of the conductive layers and the insulating layers included in the peripheral driving circuit on the substrate do not overlap with the aperture region; a number of the insulating layers included in the peripheral driving circuit is less than a number of insulating layers included in the pixel circuit.

### CROSS REFERENCES TO RELATED APPLICATIONS

This application is a national phase entry under 35 U.S.C § 371 of International Application No. PCT/CN2024/076392, filed on Feb. 6, 2024, which claims priority to Chinese Patent Application No. 202310322958.1, filed on Mar. 29, 2023 to the China National Intellectual Property Administration, and entitled “Display Panel and Display Device”, the entire content of which is incorporated herein by reference.

### TECHNICAL FIELD

The present disclosure relates to the technical field of display, and in particular to a display panel and a display device.

### BACKGROUND

Organic electroluminescent display panels (Organic Light-Emitting Diode, OLED) have gradually become the mainstream in the display field due to their excellent properties such as low power consumption, high color saturation, wide viewing angle, thin thickness, and flexibility. It can be widely used in terminal products such as smartphones, tablets, and televisions. Among them, flexible OLED products are the most prominent, gradually becoming the mainstream of OLED displays due to their ability to meet various special structures.

With the development of flexible process, there is a gradual transition from bending, folding, to elastic flexibility. Flexible and stretchable displays have received widespread attention in the market due to their broad application space. However, in the related art, flexible stretchable display products require more apertures to form island structures and bridge structures, where light-emitting devices are placed in the island region and connecting wires are placed in the bridge region to achieve the stretching function of the display panel. However, stretchable products only have stretching function in the display region, and do not have stretching function in the border region, which affects the overall stretching performance of the display panel.

### SUMMARY

Embodiments of the present disclosure provide a display panel, the display panel includes:
a substrate, where the substrate includes: a display region, a peripheral region surrounding the display region; the display region and at least part of the peripheral region include: a plurality of island regions arranged in an array, an aperture region between adjacent island regions, and a bridge region connecting adjacent island regions;
a circuit layer on a side of the substrate, where the circuit layer includes a plurality of insulating layers and a plurality of conductive layers;
where the circuit layer is divided into a plurality of pixel circuits in the display region and a plurality of peripheral driving circuits at least in the peripheral region;
orthographic projections of conductive layers and insulating layers included in the peripheral driving circuit on the substrate overlap with the island region and the bridge region;
the orthographic projections of the conductive layers and the insulating layers included in the peripheral driving circuit on the substrate do not overlap with the aperture region;
a number of the insulating layers included in the peripheral driving circuit is less than a number of insulating layers included in the pixel circuit.

In some embodiments, the pixel circuit includes: a pixel driving circuit and a light-emitting device on a side of the pixel driving circuit facing away from the substrate;
the plurality of conductive layers includes: an anode layer and a cathode layer on a side of the anode layer facing away from the substrate;
the anode layer includes an anode of the light-emitting device, and the cathode layer includes a cathode of the light-emitting device;
orthographic projections of the anode layer and the cathode layer on the substrate do not overlap with the peripheral region including the aperture region.

In some embodiments, the display panel further includes: an encapsulation layer on a side of the light-emitting device facing away from the substrate;
where an orthographic projection of the encapsulation layer on the substrate does not overlap with the aperture region;
the peripheral region includes a first peripheral region adjacent to the display region in a first direction;
the first peripheral region includes: an encapsulated coverage region adjacent to the display region, a cutting boundary region on a side of the encapsulated coverage region away from the display region in the first direction, and an encapsulated boundary region between the encapsulated coverage region and the cutting boundary region;
an orthographic projection of the encapsulation layer on the substrate does not overlap with the cutting boundary region and the encapsulated boundary region, and the orthographic projection of the encapsulation layer on the substrate covers the island regions and the bridge regions in the display region and the island regions and the bridge regions in the encapsulated coverage region;
the encapsulated coverage region includes: a circuit region adjacent to the display region, and a non-circuit region between the first circuit region and the encapsulated boundary region; orthographic projections of the conductive layers included in the peripheral driving circuit on the substrate fall into the circuit region.

In some embodiments, the plurality of conductive layers further include: a first conductive layer between the substrate and the anode layer, and a second conductive layer between the first conductive layer and the anode layer;
the pixel driving circuit includes: a first level signal line electrically connected with the anode;
the peripheral driving circuit includes: a second level signal line electrically connected with the cathode;
the first conductive layer includes the first level signal line, and the second conductive layer includes the second level signal line.

In some embodiments, the plurality of insulating layers include: a first interlayer insulating layer between the first conductive layer and the second conductive layer, and a first planarization layer between the second conductive layer and the anode layer;
an orthographic projection of the first interlayer insulating layer on the substrate does not overlap with the first peripheral region;
an orthographic projection of the first planarization layer on the substrate covers the peripheral driving circuit; and
the orthographic projection of the first planarization layer on the substrate does not overlap with the non-circuit region, the cutting boundary region and the encapsulated boundary region.

In some embodiments, the plurality of insulating layers further include: a protective layer between the first planarization layer and the anode layer;
an orthographic projection of the protective layer on the substrate overlaps with the encapsulated coverage region and the encapsulated boundary region, and the orthographic projection of the protective layer on the substrate does not overlap with the cutting boundary region.

In some embodiments, the pixel driving circuit includes a plurality of pixel driving units;
the peripheral driving circuit includes: a plurality of peripheral driving units, and a plurality of peripheral signal lines; and
the pixel driving unit and the peripheral driving unit both include a thin-film transistor and a capacitor.

In some embodiments, the plurality of conductive layers further include: a first conductive layer, and a second conductive layer between the first conductive layer and the anode layer; the first conductive layer includes: a gate of a thin-film transistor of the pixel driving unit and a gate of a thin-film transistor of the peripheral driving unit; the second conductive layer includes: a source electrode and a drain electrode of the thin-film transistor of the pixel driving unit and a source electrode and a drain electrode of the thin-film transistor of the peripheral driving unit;
the circuit layer further includes: an active layer of the thin-film transistor; the active layer is between the first conductive layer and the substrate;
the plurality of insulating layers include: a first gate insulating layer between the active layer and the first conductive layer, a first interlayer insulating layer between the first conductive layer and the second conductive layer, and a first planarization layer between the second conductive layer and the anode;
orthographic projections of the first gate insulating layer, the first interlayer insulating layer, and the first planarization layer on the substrate cover the peripheral driving circuit, and the orthographic projections of the first gate insulating layer, the first interlayer insulating layer, and the first planarization layer on the substrate do not overlap with the non-circuit region, the cutting boundary region, and the encapsulated boundary region.

In some embodiments, the plurality of insulating layers further include: a protective layer between the first planarization layer and the anode layer;
an orthographic projection of the protective layer on the substrate overlaps with the encapsulated coverage region and the encapsulated boundary region, and the orthographic projection of the protective layer on the substrate does not overlap with the cutting boundary region.

In some embodiments, the plurality of conductive layers further include: a third conductive layer between the first conductive layer and the first interlayer insulating layer;
the plurality of insulating layers further include: a second gate insulating layer between the first conductive layer and the third conductive layer;
an orthographic projection of the second gate insulating layer on the substrate covers the peripheral driving circuit, and the orthographic projection of the second gate insulating layer on the substrate does not overlap with the non-circuit region, the cutting boundary region, and the encapsulated boundary region.

In some embodiments, the plurality of conductive layers further include: a fourth conductive layer between the first planarization layer and the protective layer;
the plurality of insulating layers further include: a second planarization layer between the fourth conductive layer and the protective layer;
an orthographic projection of the second planarization layer on the substrate covers the peripheral driving circuit; and the orthographic projection of the second planarization layer on the substrate does not overlap with the non-circuit region, the cutting boundary region and the encapsulated boundary region.

In some embodiments, the peripheral signal lines include: a plurality of connecting signal lines;
two adjacent peripheral driving units in a second direction are electrically connected by the connecting signal line, the second direction intersects with the first direction;
an orthographic projection of the peripheral driving unit on the substrate falls into the island region, and an orthographic projection of the connecting signal line on the substrate passes through the bridge and extends to the island region;
the plurality of connecting signal lines include: a first signal line and a second signal line where the first signal line and the second signal line are located in different conductive layers;
at least part of the first signal line includes: a first portion and a second portion electrically connected with the first portion; the second conductive layer includes the first portion, the first conductive layer includes the second portion, an orthographic projection of the first portion on the substrate passes through the bridge region and extends to the island region, and an orthographic projection of the second portion on the substrate falls into the island region;
the fourth conductive layer includes the second signal line.

In some embodiments, in the bridge region, the orthographic projection of the first portion on the substrate and an orthographic projection of the second signal line on the substrate have an overlapping region.

In some embodiments, the plurality of peripheral signal lines include: a plurality of peripheral driving signal lines;
in the display region, the plurality of pixel driving units are divided into a plurality of rows of pixel driving units extending in the first direction and arranged in the second direction;
the plurality of peripheral driving signal lines are electrically connected with the rows of pixel driving units and the peripheral driving signal lines;
the plurality of peripheral driving signal lines are located in at least one of: the first conductive layer, the second conductive layer, the third conductive layer, or the fourth conductive layer.

In some embodiments, the plurality of insulating layers further include: a pixel defining layer between the anode layer and the cathode layer;
the pixel defining layer includes a plurality of opening regions, and orthographic projections of the opening regions on the substrate fall into an orthographic projection of the anode on the substrate;
the orthographic projections of the opening regions on the substrate do not overlap the aperture region and the first peripheral region.

In some embodiments, the protective layer includes a vent hole through a thickness of the protective layer;
an orthographic projection of vent hole on the substrate falls into the island region, and the orthographic projection of vent hole on the substrate does not overlap with an orthographic projection of the anode on the substrate.

In some embodiments, the plurality of island regions included in the display region are divided into a plurality of rows of first island regions extending in a first direction and arranged in a second direction;
the plurality of island regions included in a first peripheral region are divided into a plurality of rows of second island regions extending in the first direction and arranged in the second direction;
one row of second island regions corresponds to n rows of first island regions, where n is an integer greater than or equal to 1.

In some embodiments, the row of second island regions includes at least one peripheral driving unit;
the row of first island regions includes at least one row of pixel driving units;
the peripheral driving units included in one row of second island regions are electrically connected with rows of pixel driving units included in n rows of first island regions.

In some embodiments, in at least part of the peripheral region, a pattern of at least part of the aperture region is I-shaped.

In some embodiments, in at least part of the peripheral region, the a pattern of at least part of the aperture region includes a third portion and two fourth portions;
an extension direction of the third portion is different from an extension direction of the fourth portion, and the third portion passes through the two fourth portions.

In some embodiments, a pattern of at least part of the aperture region included in the peripheral region is the same as a pattern of at least part of the aperture region included in the display region.

In some embodiments, in at least part of the peripheral region, the bridge region and the aperture region are connected with the row of second island regions in the second direction; the bridge region includes a curved portion curving and extending in the second direction, and the aperture region is between two adjacent bridge regions in the first direction.

In some embodiments, the curved portion includes a plurality of arcuate portions connected in sequence.

In some embodiments, a pattern of at least part of the aperture region included in the display region is different from a pattern of at least part of the aperture region included in the peripheral region.

In some embodiments, a pattern of at least part of the aperture region included in the display region is I-shaped.

Embodiments of the present disclosure provide a display device including the display panel provided by embodiments of the present disclosure.

### BRIEF DESCRIPTION OF FIGURES

In order to more clearly illustrate the technical solutions in embodiments of the present disclosure, the following will be a brief introduction to the description of embodiments of the need to use the accompanying drawings, it is obvious that the following description of the accompanying drawings is only some of embodiments of the present disclosure, for the person of ordinary skill in the field, in the premise of the creative labor, but also according to these drawings, can also be obtained from the other drawings.

FIG. 1 shows a schematic diagram of a structure of a display panel provided by embodiments of the present disclosure.

FIG. 2 shows another schematic diagram of a structure of a display panel provided by embodiments of the present disclosure.

FIG. 3 shows another schematic diagram of a structure of a display panel provided by embodiments of the present disclosure.

FIG. 4 shows another schematic diagram of a structure of a display panel provided by embodiments of the present disclosure.

FIG. 5 shows another schematic diagram of a structure of a display panel provided by embodiments of the present disclosure.

FIG. 6 shows a schematic diagram of an orthographic projection of a first conductive layer on a substrate provided by embodiments of the present disclosure.

FIG. 7 shows a schematic diagram of an orthographic projection of a first interlayer insulating layer on a substrate provided by embodiments of the present disclosure.

FIG. 8 shows a schematic diagram of an orthographic projection of a second conductive layer on a substrate provided by embodiments of the present disclosure.

FIG. 9 shows a schematic diagram of an orthographic projection of a first planarization layer on a substrate provided by embodiments of the present disclosure.

FIG. 10 shows a schematic diagram of an orthographic projection of a first protective layer on a substrate provided by embodiments of the present disclosure.

FIG. 11 shows a schematic diagram of an orthographic projection of a second protective layer on a substrate provided by embodiments of the present disclosure.

FIG. 12 shows a schematic diagram of an orthographic projection of an anode layer on a substrate provided by embodiments of the present disclosure.

FIG. 13 shows a schematic diagram of an orthographic projection of a pixel defining layer on a substrate provided by embodiments of the present disclosure.

FIG. 14 shows a schematic diagram of an orthographic projection of an encapsulation layer on a substrate provided by embodiments of the present disclosure.

FIG. 15 shows a schematic diagram of an orthographic projection of an active layer on a substrate provided by embodiments of the present disclosure.

FIG. 16 shows another schematic diagram of an orthographic projection of a first conductive layer on a substrate provided by embodiments of the present disclosure.

FIG. 17 shows a schematic diagram of an orthographic projection of a third conductive layer on a substrate provided by embodiments of the present disclosure.

FIG. 18 shows another schematic diagram of an orthographic projection of a first interlayer insulating layer on a substrate provided by embodiments of the present disclosure.

FIG. 19 shows another schematic diagram of an orthographic projection of a second conductive layer on a substrate provided by embodiments of the present disclosure.

FIG. 20 shows another schematic diagram of an orthographic projection of a first planarization layer on a substrate provided by embodiments of the present disclosure.

FIG. 21 shows a schematic diagram of an orthographic projection of a fourth conductive layer on a substrate provided by embodiments of the present disclosure.

FIG. 22 shows a schematic diagram of an orthographic projection of a second planarization layer on a substrate provided by embodiments of the present disclosure.

FIG. 23 shows another schematic diagram of an orthographic projection of a first protective layer on a substrate provided by embodiments of the present disclosure.

FIG. 24 shows another schematic diagram of an orthographic projection of a second protective layer on a substrate provided by embodiments of the present disclosure.

FIG. 25 shows another schematic diagram of an orthographic projection of an anode layer on a substrate provided by embodiments of the present disclosure.

FIG. 26 shows another schematic diagram of an orthographic projection of a pixel defining layer on a substrate provided by embodiments of the present disclosure.

FIG. 27 shows another schematic diagram of an orthographic projection of an encapsulation layer on a substrate provided by embodiments of the present disclosure.

FIG. 28 shows a schematic diagram of an orthographic projection of a peripheral driving circuit on a substrate provided in embodiments of the present disclosure.

FIG. 29 shows a schematic diagram of a peripheral driving unit provided in embodiments of the present disclosure.

FIG. 30 shows another schematic diagram of a peripheral driving unit provided in embodiments of the present disclosure.

FIG. 31 shows another schematic diagram of a structure of a display panel provided by embodiments of the present disclosure.

FIG. 32 shows another schematic diagram of a structure of a display panel provided by embodiments of the present disclosure.

FIG. 33 shows another schematic diagram of an orthographic projection of an active layer on a substrate provided by embodiments of the present disclosure.

FIG. 34 shows another schematic diagram of an orthographic projection of a first conductive layer on a substrate provided by embodiments of the present disclosure.

FIG. 35 shows another schematic diagram of an orthographic projection of a third conductive layer on a substrate provided by embodiments of the present disclosure.

FIG. 36 shows another schematic diagram of an orthographic projection of a first interlayer insulating layer on a substrate provided by embodiments of the present disclosure.

FIG. 37 shows another schematic diagram of an orthographic projection of a second conductive layer on a substrate provided by embodiments of the present disclosure.

FIG. 38 shows another schematic diagram of an orthographic projection of a first planarization layer on a substrate provided by embodiments of the present disclosure.

FIG. 39 shows another schematic diagram of an orthographic projection of a fourth conductive layer on a substrate provided by embodiments of the present disclosure.

FIG. 40 shows a schematic diagram of an orthographic projection of a part of a film layers in a peripheral driving circuit on a substrate provided by embodiments of the present disclosure.

FIG. 41 shows another schematic diagram of an orthographic projection of a peripheral driving circuit on a substrate provided by embodiments of the present disclosure.

FIG. 42 shows another schematic diagram of a structure of a display panel provided by embodiments of the present disclosure.

FIG. 43 shows another schematic diagram of a structure of a display panel provided by embodiments of the present disclosure.

### DETAILED DESCRIPTION

In order to make the purposes, technical solutions and advantages of embodiments of the present disclosure clearer, the technical solutions of embodiments of the present disclosure will be described clearly and completely in the following in connection with the accompanying drawings of embodiments of the present disclosure. Obviously, the described embodiments are part of embodiments of the present disclosure, but not all of embodiments. Moreover, embodiments and the features in embodiments of the present disclosure can be combined with each other without conflict. Based on the described embodiments of the present disclosure, all other embodiments obtained by a person of ordinary skill in the art without the need for creative labor are within the scope of protection of the present disclosure.

Unless otherwise defined, technical or scientific terms used in this disclosure should have the ordinary meaning understood by a person of ordinary skill in the art to which this disclosure pertains. The terms “first,” “second,” and the like, as used in this disclosure, do not indicate any order, number, or importance, but are used only to distinguish between different components. The words “including” or “comprising” and the like are intended to mean that the component or object preceded by the word encompasses the components or objects listed after the word and their equivalents, and does not exclude other components or objects. Terms such as “connected” or “coupled” are not limited to physical or mechanical connections, but may include electrical connections, whether direct or indirect.

And the same or similar symbols throughout indicate the same or similar elements or elements with the same or similar functions.

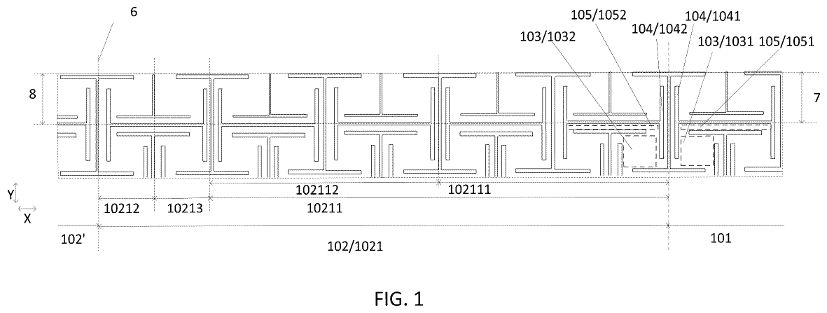

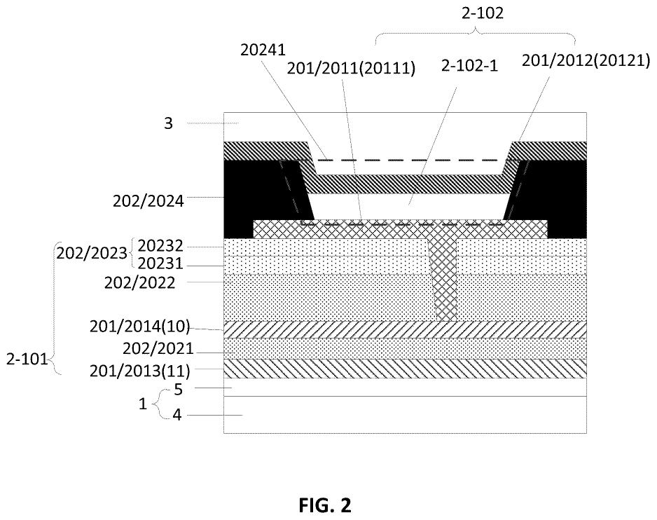

Embodiments of the present disclosure provide a display panel, the display panel includes:
as shown in FIG. 1, the substrate 1, includes: a display region 101, a peripheral region 102 surrounding the display region 101; the display region 101 and at least part of the peripheral region 102 include: a plurality of island regions 103 arranged in an array, an aperture region 104 between adjacent island regions 103, and a bridge region 105 connecting the adjacent island regions 103; in order to facilitate the differentiation, the island regions 103, the aperture region 104, and the bridge region 105 located in display region 101 are named the first island region 1031, the first aperture region 1041, and the first bridge region 1051; and the island region 103, the aperture region 104, and the bridge region 105 located in peripheral region 102 are named the second island region 1032, the second aperture region 1042, and the second bridge region 1052;
as shown in FIGS. 2 to 5, the circuit layer 2 on one side of the substrate 1, includes a plurality of insulating layers 202 and a plurality of conductive layers 201; the circuit layer 2 is divided into pixel circuits 2-1 disposed in the display region 101 and peripheral driving circuits 2-2 disposed at least in the peripheral region 102; orthographic projections of conductive layers and insulating layers included in the peripheral driving circuit on the substrate 1 overlap with the island region 103 (i.e., the second island region 1032) and the bridge region 105 (i.e., the second bridge region 1052); the orthographic projections of the conductive layers 201 and the insulating layers 202 included in the peripheral driving circuit 2-2 on the substrate 1 do not overlap with the aperture region 104 (i.e., the second aperture region 1042); a number of the insulating layers 202 included in the peripheral driving circuit 2-2 is less than a number of insulating layers 202 included in the pixel circuit 2-1.

Embodiments of the present disclosure provide a display panel that can be applied to a stretchable display product, the display region includes the island region, the bridge region, and the aperture region, and the bridge region is deformed by a force so that the display region can realize a stretching function. Moreover, at least part of the peripheral region surrounding the display region also includes the island region, the bridge region, and the aperture region, so that the peripheral region can also realize the stretching function. Furthermore, when the peripheral driving circuit is provided in the peripheral region including the aperture region, the orthographic projection of the peripheral driving circuit on the substrate and the aperture region do not overlap with each other, and the number of insulating layers of the peripheral driving circuit is less than the number of insulating layers of pixel circuits in the display region, which is more favorable to improving the stretching performance of the peripheral region.

In some embodiments, the orthographic projections of the conductive layer and the insulating layer included in the pixel circuit on the substrate overlap with the island region (i.e., a first island region) and the bridge region (i.e., a first bridge region), and the orthographic projections of the conductive layer and the insulating layer included in the pixel circuit on the substrate do not overlap with the aperture region (i.e., a first aperture region). That is, the orthographic projections of the conductive layer and the insulating layer included in the whole circuit layer on the substrate overlap with the island region and the bridge region, and the orthographic projections of the conductive layer and the insulating layer included in the whole circuit layer on the substrate do not overlap with the aperture region.

In some embodiments, as shown in FIGS. 2 to 5, the substrate includes a flexible substrate 4. The material of the flexible substrate includes, for example, polyimide. The substrate may also include a buffer layer 5 disposed on the side of the flexible substrate 4 facing the circuit layer 2.

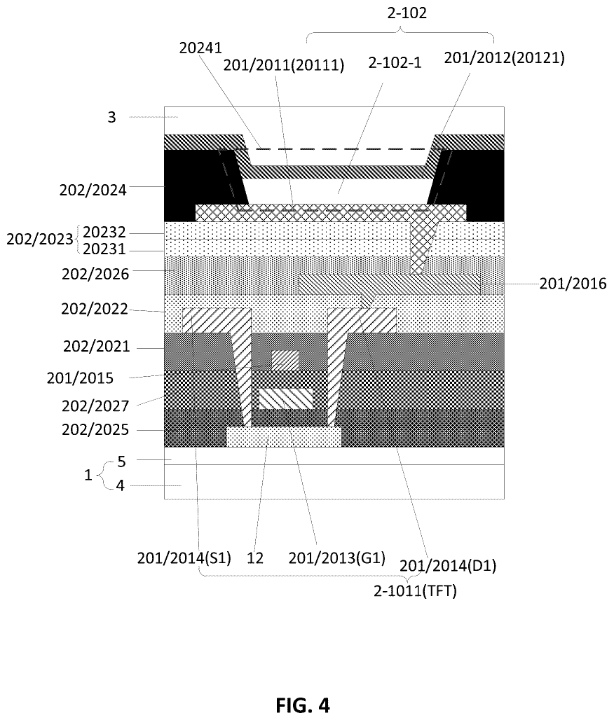

In some embodiments, as shown in FIGS. 2 and 4, the pixel circuit 2-1 includes: a pixel driving circuit 2-101 and a light-emitting device 2-102 located on the side of the pixel driving circuit 2-101 facing away from the substrate 1; the pixel driving circuit 2-101 is electrically connected with the light-emitting device 2-102; the plurality of conductive layers 201 include: an anode layer 2011 and a cathode layer 2012 located on the side of the anode layer 2011 facing away from the substrate 1; the anode layer 2011 includes the anode 20111 of the light-emitting device 2-102, and the cathode layer 2012 includes the cathode 20121 of the light-emitting device 2-102.

It should be noted that, in FIG. 2, only a cross-sectional view of the island region corresponding to one light-emitting device is shown.

In some embodiments, the orthographic projections of the anode layer and the cathode layer on the substrate do not overlap with the peripheral region including the aperture region.

That is, in the display panel provided in embodiments of the present disclosure, the anode layer and the cathode layer have no pattern in the peripheral region including the aperture region, can reduce the number of film layers in the peripheral region including the aperture region, and improve the stretchable capability of the peripheral region.

In some embodiments, as shown in FIGS. 2 and 4, the light-emitting device 2-102 further includes a light-emitting functional layer 2-102-1 between the anode and the cathode.

In some embodiments, the light-emitting device in the display panel provided by the embodiments of the present disclosure is, for example, an organic light-emitting diode (OLED). The light-emitting functional layer includes, for example, an organic light-emitting layer. It may also include at least one of: an electron injection layer, an electron transport layer, a hole blocking layer, a hole injection layer, a hole transport layer, and an electron blocking layer.

In some embodiments, the orthographic projection of the light-emitting functional layer on the substrate falls only into the display region and does not overlap with the aperture region.

In some embodiments, the display panel includes a plurality of sub-pixels, and one sub-pixel corresponds to at least one light-emitting device. The light emitting region of the light-emitting device is the light emitting region of the sub-pixel. The plurality of sub-pixels arranged consecutively in a first direction form a pixel, and at least one pixel is included in an island region of the display region, i.e., a first island region. The orthographic projections of the anode and the light-emitting function layer on the substrate are located only in the first island region. The cathode may, for example, be provided as a whole layer with the aperture region removed, that is, the orthographic projection of the cathode on the substrate may cover the first island region as well as the first bridge region.

In some embodiments, three sub-pixels arranged consecutively in a first direction form a pixel, the three sub-pixels are a red sub-pixel, a blue sub-pixel, and a green sub-pixel, respectively. Of course, more sub-pixels may be used to form a pixel.

In some embodiments, as shown in FIG. 2, the plurality of insulating layers 202 include: a pixel defining layer 2024; the pixel defining layer 2024 is between the anode layer 2011 and the cathode layer 2012; the pixel defining layer 2024 includes a plurality of opening regions 20241, orthographic projections of the opening regions 20241 on the substrate 1 fall into the orthographic projections of the anode 20111 on the substrate 1.

The orthographic projection of the pixel defining layer 2024 on the substrate 1 does not overlap with the aperture region 104, and the orthographic projection of the pixel defining layer 2024 on the substrate 1 does not overlap with the first peripheral region (not shown in figures).

The display panel provided in embodiments of the present disclosure, since the first peripheral region does not include the light-emitting device, the first peripheral region may not be provided with the pixel defining layer, so that the number of film layers in the first peripheral region may be reduced, and the stretchable capability of the first peripheral region may be improved.

In some embodiments, the opening region of the pixel definition layer corresponds to the light-emitting region of the light-emitting device. The pixel definition layer covers the edge of the anode.

In some embodiments, the orthographic projection of the pixel definition layer on the substrate and the bridge region do not overlap with each other. That is, the pixel definition layer is only arranged in the first island region, which can reduce the number of film layers in the first bridge region and improve the stretchable capability of the display region.

In some embodiments, as shown in FIGS. 2 to 5, the display panel further includes: an encapsulation layer 3 disposed on the side of the light-emitting device 2-102 facing away from the substrate 1; an orthographic projection of the encapsulation layer 3 on the substrate 1 does not overlap with the aperture region 104.

In some embodiments, the encapsulation layer is used to prevent water and oxygen erosion of light-emitting devices, the encapsulation layer needs to cover the light-emitting devices, but also need to extend to the peripheral region.

In some embodiments, the encapsulation layer includes an inorganic encapsulation layer, an organic encapsulation layer, and an inorganic encapsulation layer provided in a stack.

In some embodiments, as shown in FIG. 1, the peripheral region 102 includes a first peripheral region 1021 adjacent to the display region 101 in the first direction X; the first peripheral region 1021 includes: an encapsulated coverage region 10211 adjacent to the display region 101, a cutting boundary region 10212 on a side of the encapsulated coverage region 10211 away from the display region 101 in the first direction X, and an encapsulated boundary region 10213 between the encapsulated coverage region 10211 and the cutting boundary region 10212.

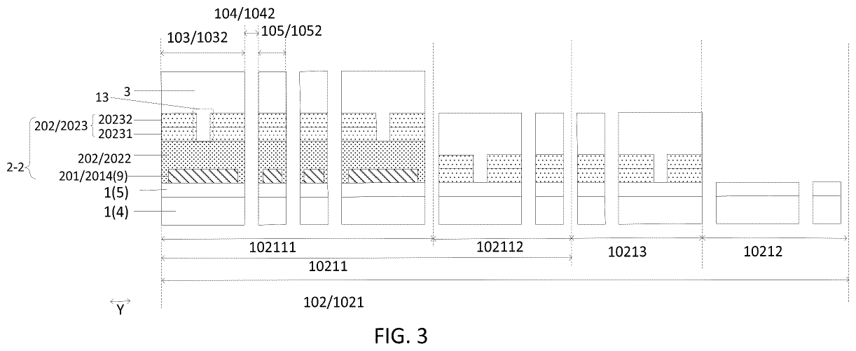

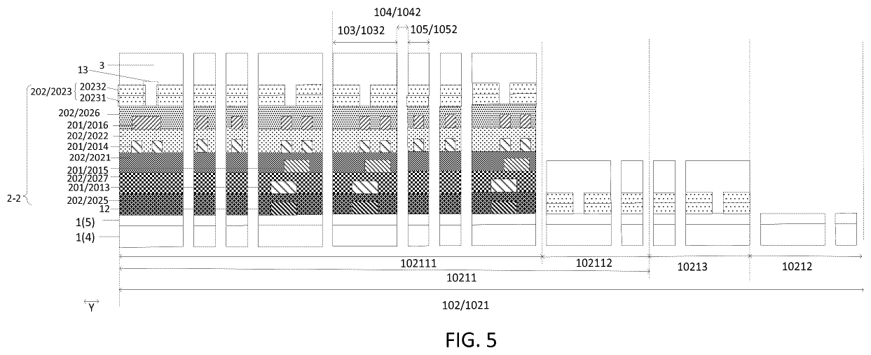

As shown in FIGS. 3 and 5, an orthographic projection of the encapsulation layer 3 on the substrate 1 does not overlap with the cutting boundary region 10212 and the encapsulated boundary region 10213, and the orthographic projection of the encapsulation layer 3 on the substrate 1 covers the island regions (such as, the first island region, not shown in figures) and the bridge regions (such as, the first bridge region, not shown in figures) in the display region and the island regions 103 (such as, the second island region 1032) and the bridge regions 105 (such as, the second bridge region 1052) in the encapsulated coverage region 10211.

It should be noted that the boundary of the encapsulated coverage region away from the display region corresponds to the boundary of the encapsulation layer in the first peripheral region. In the production process of the display panel, for example, the mother board is first produced, then the mother board is cut for the first time to obtain a plurality of pieces, and then each piece is cut for the second time to obtain the display panel. As shown in FIG. 1, the edge of the cutting boundary region 10212 away from the display region 101 corresponds to the cutting line 6 of the second cutting, and the region labeled 102′ in FIG. 1 is removed by cutting. The cutting boundary region is the region adjacent to the cutting line, the encapsulated boundary region is a region between a boundary of the encapsulation layer and the cutting boundary region, in order to facilitate the cutting, usually the number of film layers in the cutting boundary region of is less than the number of film layers in the encapsulated boundary region.

In some embodiments, as shown in FIG. 1, the encapsulated coverage region 10211 includes: a circuit region 102111 adjacent to the display region 101, and a non-circuit region 102112 located between the circuit region 102111 and the encapsulated boundary region 10213. As shown in FIGS. 3 and 5, orthographic projections of the conductive layers 201 included in the peripheral driving circuit 2-2 on the substrate 1 fall into the circuit region 102111.

In some embodiments, the display panel provided by embodiments of the present disclosure is a Passive Matrix Organic Light-Emitting Diode (Passive matrix OLED, PMOLED).

In some embodiments, as shown in FIGS. 2 and 3, the plurality of conductive layers 201 further includes: a first conductive layer 2013 between the substrate 1 and the anode layer 2011, and a second conductive layer 2014 between the first conductive layer 2013 and the anode layer 2011.

The pixel driving circuit 2-101 includes: a first level signal line 11 electrically connected with the anode 20111; the peripheral driving circuit 2-2 includes a second level signal line 9 electrically connected with the cathode 20121; the first conductive layer 2013 includes the first level signal line 11, and the second conductive layer 2014 includes the second level signal line 9.

In some embodiments, as shown in FIG. 2, the second conductive layer 2014 also includes a plurality of first adapter portions 10, and the anode 20111 is electrically connected with the first level signal line 11 through the adapter portions 10. Thereby, it can avoid the distance between the anode and the first conductive layer being too far, which may cause overlapping and disconnection, and improve the yield of the display panel.

In some embodiments, the first level signal line is a signal line for transmitting a high level signal, and the second level signal line is a signal line for transmitting a low level signal. The second level signal line extends, for example, from the first peripheral region to the display region and is electrically connected with the cathode. For example, the orthographic projection of the second level signal line on the substrate includes a portion located in the island region and a portion located in the bridge region.

In some embodiments, as shown in FIGS. 2 and 3, the plurality of insulating layers 202 include: a first interlayer insulating layer 2021 between the first conductive layer 2013 and the second conductive layer 2014, and a first planarization layer 2022 between the second conductive layer 2014 and the anode layer 2011;
an orthographic projection of the first interlayer insulating layer 2021 on the substrate 1 does not overlap with the first peripheral region 1021;
an orthographic projection of the first planarization layer on the substrate 1 covers the peripheral driving circuit 2-2; and the orthographic projection of the first planarization layer 2022 on the substrate 1 does not overlap with the non-circuit region 102112, the cutting boundary region 10212 and the encapsulated boundary region 10213.

That is, in the display panel provided in embodiments of the present disclosure, the first interlayer insulating layer is not arranged in the first peripheral region, and the stretchable capability of the first peripheral region can be improved by reducing the number of film layers of the insulating layer in the first peripheral region. Moreover, in the first peripheral region, the first planarization layer covering the second level signal line is provided only in the circuit region, and is removed from the non-circuit region, the cutting boundary region, and the encapsulated boundary region, so that the number of film layers in the first peripheral region in the region other than the circuit region can be reduced while protecting the second level signal line to improve the stretchable capability of a portion of the first peripheral region.

In some embodiments, in a region where the first interlayer insulating layer and the first planarization layer are provided, the first interlayer insulating layer and the first planarization layer have apertures corresponding to the aperture regions. The orthographic projections of the apertures in the first interlayer insulating layer and the first planarization layer on the substrate overlap with the aperture regions.

In some embodiments, as shown in FIGS. 2 and 3, the plurality of insulating layers 202 further include: a protective layer 2023 between the first planarization layer 2022 and the anode layer 2011;
an orthographic projection of the protective layer 2023 on the substrate 1 overlaps with the encapsulated coverage region 10211, and the encapsulated boundary region 10213, and the orthographic projection of the protective layer on the substrate 1 does not overlap with the cutting boundary region 10212.

That is, in the cutting boundary region need to remove the protective layer, so that the encapsulated boundary region only has a substrate, easy to cut.

In some embodiments, in the region where the protective layer is provided, the protective layer has apertures corresponding to the aperture regions. The orthographic projections of the apertures in the protective layer on the substrate overlap with the aperture regions.

In some embodiments, the anode is electrically connected with the adapter portion through an aperture through the protective layer and the planarization layer, and the adapter portion is electrically connected with the first level signal line through an aperture through the first interlayer insulating layer. The cathode is electrically connected with the second level signal line through an aperture through the pixel defining layer, the protective layer, and the planarization layer.

In some embodiments, as shown in FIGS. 2 and 3, the protective layer 2023 includes a first protective layer 20231 and a second protective layer 20232 disposed on the side of the first protective layer 20231 facing away from the substrate 1. The protective layer 2023 includes vent holes 13 running through the thickness of the first protective layer 20231 as well as the second protective layer 20232.

It should be noted that, due to the protective layer below the planarization layer, in the subsequent production process of the display panel, the planarization layer will be deflated, if the protective layer is not set up vent holes, the gas will lead to the protective layer bulging cracks, which will lead to the film above the protective layer cracked, such as, the light-emitting device of the film layer, affecting the yield of the display panel production.

In some embodiments, both the display region and the surrounding region, the protective layer needs to be provided with vent holes. In the display region, the orthographic projections of the vent holes on the substrate do not overlap with the orthographic projection of the anode on the substrate. In the peripheral region, the orthographic projections of the vent holes on the substrate overlap with the orthographic projection of the conductive layer included in the peripheral driving circuit on the substrate. The pattern of the vent holes in the peripheral region may be the same as the pattern of the vent holes in the display region.

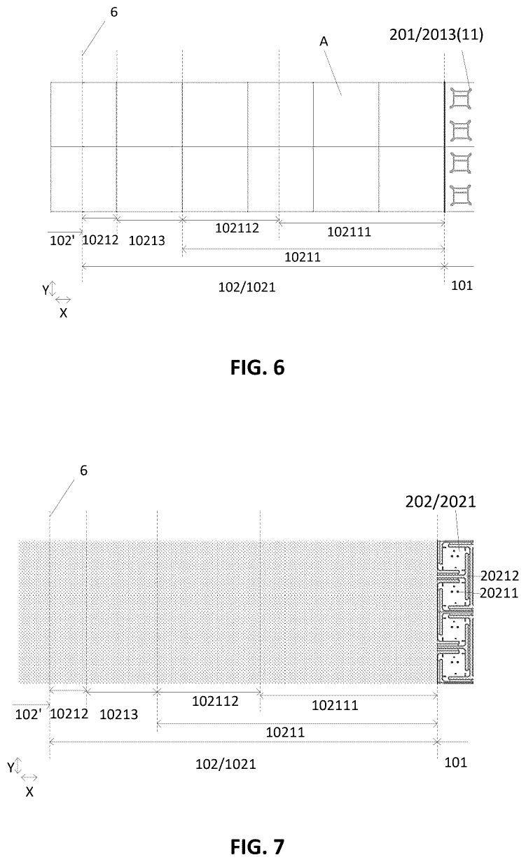

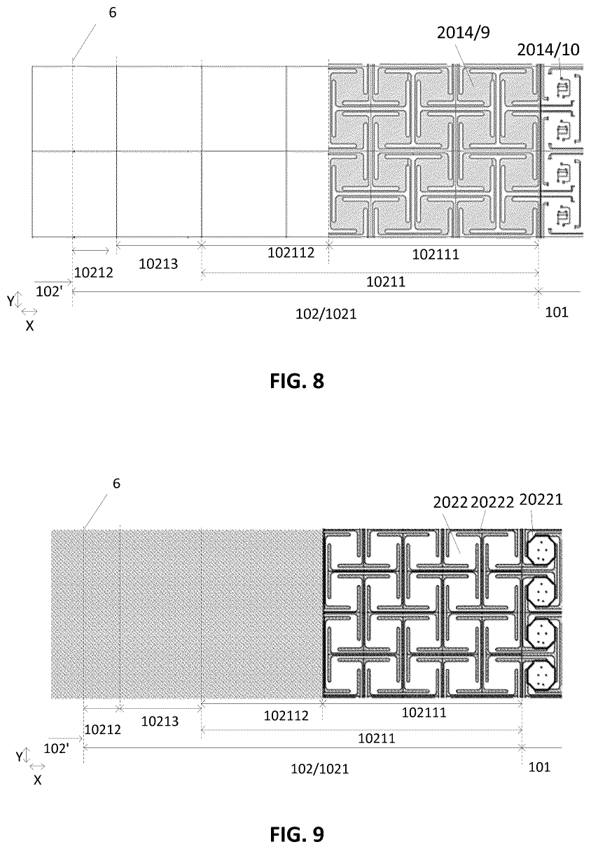

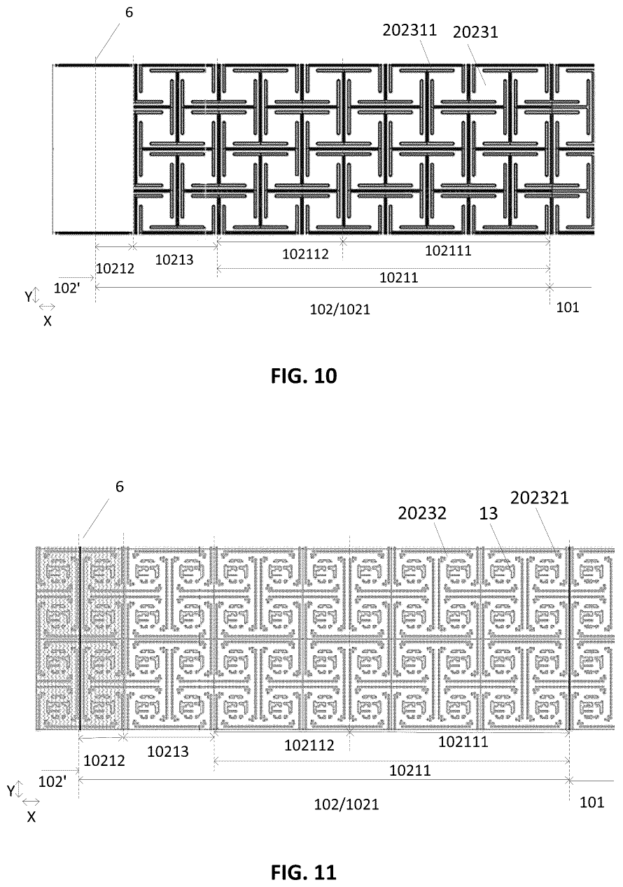

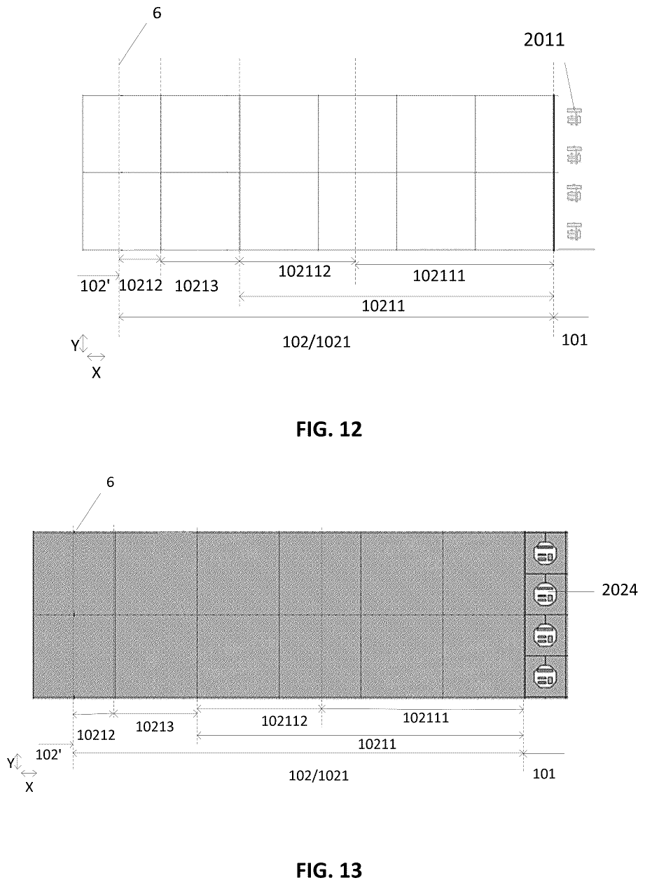

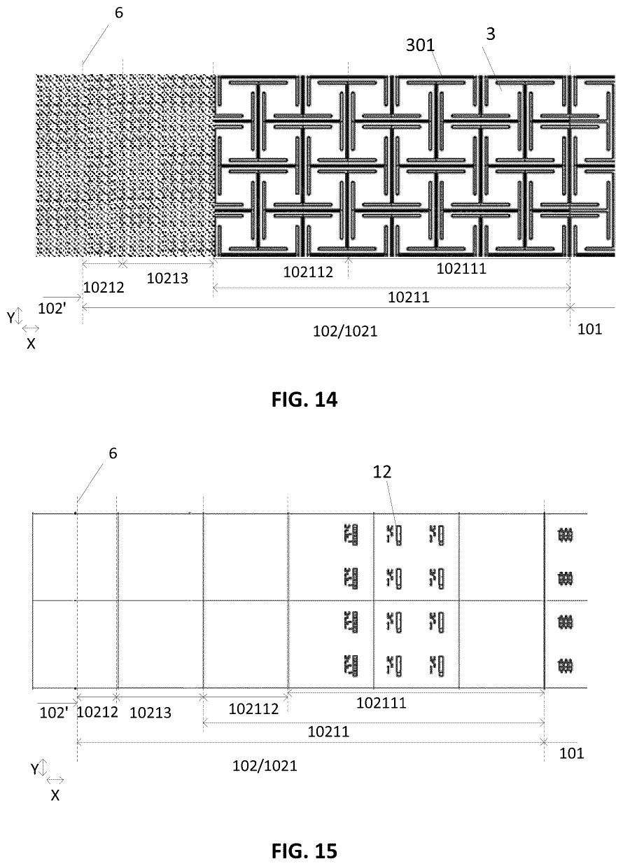

Next, the manufacturing process of the PMOLED display panel and the patterns of some film layers provided by embodiments of the present disclosure are introduced with examples.
1. Form a buffer layer on a flexible substrate.
2. Form a pattern of the first conductive layer on the side of the buffer layer facing away from the flexible substrate; the pattern of the first conductive layer 2013 is as shown in FIG. 6, and the first conductive layer 2013 is only located in the display region 101. It should be noted that a square region in FIG. 6, namely region A, corresponds to four island regions.
3. Form a pattern of the first interlayer insulating layer on a side of the first conductive layer facing away from the flexible substrate; the pattern of the first interlayer insulating layer 2021 is shown in FIG. 7, the first interlayer insulating layer 2021 is located only in the display region 101. After the formation of the first interlayer insulating layer 2021, the first peripheral region 1021 and the corresponding first interlayer insulating layer 2021 of the opening area of the display area 101 are removed, and a first aperture 20211 is formed. The first interlayer insulating layer 2021 has a first opening 20212 in the region corresponding to the opening region of the display region 101. It should be noted that the white region in FIG. 7 is the region retained by the first interlayer insulating layer.
4. Form a pattern of a second conductive layer on the side of the first interlayer insulating layer facing away from the flexible substrate, the pattern of the second conductive layer 2014 is shown in FIG. 8, including an adapter portion 10 and a second level signal line 9, the pattern of the adapter portion 10 is disposed in the display region 101, the adapter portion 10 is electrically connected through a first aperture (not shown) with the first level signal line (not shown), and the second level signal line 9 is disposed in the circuit region 102111.
5. Form a pattern of a first planarization layer on the side of the second conductive layer facing away from the flexible substrate, and the pattern of the first planarization layer 2022 is shown in FIG. 9, and is located only in the display region 101 and in the circuit region 102111. The first planarization layer 2022 has a second aperture 20221 in the region where the anode is electrically connected with the second conductive layer, and the first planarization layer 2022 has a second aperture 2022 in the region corresponding to the aperture region. It should be noted that the white region in FIG. 9 is the region retained by the first planarization layer.
6. Form a pattern of the first protective layer on the side of the first planarization layer facing away from the flexible substrate, the pattern of the first protective layer 20231 is shown in FIG. 10, the pattern of the first protective layer 20231 is located in the display region 101, the encapsulated coverage region 10211, and the encapsulated boundary region 10213. That is, after the formation of the first protective layer 20231, the patterning process removes the first protective layer 20231 in the aperture region in the display region 101, the aperture region in encapsulated coverage region 10211, the aperture region in the encapsulated boundary region 10213, and the cutting boundary region 10212. In the aperture region of the display region 101, the aperture region of the encapsulated coverage region 10211, the aperture region of the encapsulated boundary region 10213, the first protective layer 20231 has a third aperture 202311 that corresponds to the aperture region. It should be noted that after the formation of the first protective layer, no vent holes are formed in the first protective layer for the time being. The white region in FIG. 10 is the region retained by the first protective layer.
7. Form the pattern of the second protective layer on the side of the first protective layer facing away from the flexible substrate, and the pattern of the vent holes 13 is formed, and the pattern of the second protective layer 20232 is shown in FIG. 11. The second protective layer 20232 is located in the display region 101, the encapsulated coverage region 10211, and the encapsulated boundary region 10213. That is, after the formation of the second protective layer 20232, the pattern process removes the second protective layer 20232 in the aperture region in the display region 101, the aperture region in encapsulated coverage region 10211, the aperture region in the encapsulated boundary region 10213, and the cutting boundary region 10212. The second protective layer 20232 has a fourth aperture 202321 that corresponds to the aperture region. It should be noted that, in this step, a pattern of vent holes 13 is formed that penetrate through the second protective layer and the first protective layer. The white region in FIG. 11 is the region retained by the second protective layer.
8. As shown in FIG. 12, form a pattern of an anode layer 2011, with the anode layer 2011 located only in the island region of the display region 101.
9. Form a pattern of the pixel definition layer, and the pattern of the pixel definition layer 2024 is shown in FIG. 13, and the pixel definition layer 2024 is located only in the island region of the display region 101. That is, after forming the pixel definition layer, a patterning process is used to remove the pixel definition layer from the opening region, the first peripheral region 1021, and the aperture and bridge regions of the display region 101. The white region in FIG. 13 is the region retained by the pixel definition layer 2024.
10. Form the patterns of the light-emitting functional layer and the pattern of the cathode.
11. Form the pattern of the encapsulation layer, the pattern of the encapsulation layer 3 is shown in FIG. 14, the encapsulation layer 3 is located in the display region 101 and the encapsulation coverage region 10211, after forming the encapsulation layer 3, the encapsulation layer 3 in the aperture region in the display region 101, the aperture region in encapsulated coverage region 10211, the encapsulated boundary region 10213, and the cutting boundary region 10212 is removed. The encapsulation layer 3 has the fifth corresponding to the aperture region. The white region in FIG. 14 is the region retained by the encapsulation layer 3.
12. Form patterns of aperture regions on the flexible substrate as well as on the buffer layer.

Of course, in some embodiments, the display panel can also be AMOLED.

In some embodiments, the pixel driving circuit includes a plurality of pixel driving units; the peripheral driving circuit includes: a plurality of peripheral driving units, and a plurality of peripheral signal lines; the pixel driving unit as well as the peripheral driving unit include thin-film transistors and capacitors.

In some embodiments, as shown in FIGS. 4 and 5, the plurality of conductive layers 201 also includes: a first conductive layer 2013, and a second conductive layer 2014 between the first conductive layer 2013 and the anode layer 2011. The conductive layer 2013 includes the gate electrode G of the thin-film transistor TFT, and the second conductive layer 2014 includes the source electrode S and the drain electrode D of the thin-film transistor TFT.

The circuit layer 2 further includes: an active layer 12 of a thin-film transistor; the active layer 12 is between the first conductive layer 2013 and the substrate 1.

The plurality of insulating layers 202 include: a first gate insulating layer 2025 between the active layer 12 and the first conductive layer 2013; a first interlayer insulating layer 2021 between the first conductive layer 2013 and the second conductive layer 2014, and a first planarization layer 2022 between the second conductive layer 2014 and the anode layer 2011.

The orthographic projections of the first gate insulating layer 2025, the first interlayer insulating layer 2021, and the first planarization layer 2022 on the substrate 1 cover the peripheral driving circuit 2-2, and the orthographic projections of the first gate insulating layer 2025, the first interlayer insulating layer 2021, and the first planarization layer 2022 on the substrate 1 do not overlap with the non-circuit region 102112, the cutting boundary region 10212, and the encapsulated boundary region 10213.

That is, as shown in FIG. 4, the first conductive layer 2013 includes the gate electrode G1 of the thin-film transistor TFT of the pixel driving unit 2-1011; the first conductive layer also includes: the gate electrode of the thin-film transistor of the peripheral driving unit. It should be noted that, FIG. 5 only illustrates the conductive layer 201 included in the peripheral driving circuit 2-2, and the pattern of the conductive layer 201 does not represent the actual cross-sectional pattern of the conductive layer 201. As shown in FIG. 4, the second conductive layer 2014 includes the source electrode S1 and the drain electrode D1 of the thin-film transistor TFT of the pixel driving unit 2-1011; the second conductive layer also includes the source electrode and the drain electrode of the thin-film transistor of the peripheral driving unit.

That is, in the display panel provided by embodiments of the present disclosure, in the first peripheral region, the first gate insulating layer, the first interlayer insulating layer, and the first planarization layer are provided only in the circuit region, and are removed in the non-circuit region, the cutting boundary region, and the encapsulated boundary region, so as to reduce the number of film layers in the first peripheral region in the region other than the circuit region, and to improve the stretchable capability of a portion of the first peripheral region.

In the AMOLED display panel provided by the embodiment of the present disclosure, the thin-film transistor has a top gate structure, and the source electrode and drain electrode of the thin-film transistor are respectively in contact with the conductive region of the active layer through holes penetrating through the first interlayer insulating layer, the first gate insulating layer.

In some embodiments, as shown in FIGS. 4 and 5, the plurality of insulating layers 202 further include: a protective layer 2023 between the first planarization layer 2022 and the anode layer 2011.

The orthographic projection of the protective layer 2023 on the substrate 1 overlaps with the encapsulated coverage region 10211, and the encapsulated boundary region 10213, and the orthographic projection of the protective layer 2023 on the substrate 1 does not overlap with the cutting boundary region 10212.

That is, in the cutting boundary region need to remove the protective layer, so that the encapsulated boundary region only has a substrate, easy to cut.

In some embodiments, as shown in FIGS. 4 and 5, the plurality of conductive layers 201 further include: a third conductive layer 2015 between the first conductive layer 2013 and the first interlayer insulating layer 2021.

The plurality of insulating layers 202 further include: a second gate insulating layer 2027 between the first conductive layer 2013 and the third conductive layer 2015.

The orthographic projection of the second gate insulating layer 2027 on the substrate 1 covers the peripheral driving circuit 2-2, and the orthographic projection of the second gate insulating layer 2027 on the substrate 1 does not overlap with the non-circuit region 102112, the cutting boundary region 10212, and the encapsulated boundary region 10213.

That is, in the display panel provided by embodiments of the present disclosure, in the first peripheral region, the second gate insulating layer is provided only in the circuit region and removed in the non-circuit region, the cutting boundary region, and the encapsulated boundary region, which can reduce the number of film layers in the first peripheral region in the region other than the circuit region, and improve the stretchable capability of a portion of the first peripheral region.

In some embodiments, the first conductive layer further includes a first electrode of the capacitor; the third conductive layer includes a second electrode of the capacitor.

In some embodiments, as shown in FIGS. 4 and 5, the plurality of conductive layers 201 further include: a fourth conductive layer 2016 between the first planarization layer 2022 and the protective layer 2023.

The plurality of insulating layers 202 further include: a second planarization layer 2026 between the fourth conductive layer 2016 and the protective layer 2023.

The orthographic projection of the second planarization layer 2026 on the substrate 1 covers the peripheral driving circuit 2-2; and the orthographic projection of the second planarization layer 2026 on the substrate 1 does not overlap with the non-circuit region 102112, the cutting boundary region 10212 and the encapsulated boundary region 10213.

That is, in the display panel provided in embodiments of the present disclosure, in the first peripheral region, the second interlayer insulating layer and the second planarization layer are provided only in the circuit region, and are removed in the non-circuit region, the cutting boundary region, and the encapsulated boundary region, which can reduce the number of film layers in the first peripheral region in the region outside the circuit region, and improve the stretchable capability of a portion of the first peripheral region.

In some embodiments, the fourth conductive layer includes, for example, a third adapter portion located in the display region, and the anode is electrically connected with the drain electrode of the thin-film transistor via the third adapter portion.

In some embodiments, as shown in FIGS. 4 and 5, the plurality of insulating layers 202 further include: a protective layer 2023 between the second planarization layer 2026 and the anode layer 2011.

The orthographic projection of the protective layer 2023 on the substrate 1 overlaps with the encapsulated coverage region 10211, and the encapsulated boundary region 10213, and the orthographic projection of the protective layer 2023 on the substrate 1 does not overlap with the cutting boundary region 10212.

That is, in the cutting boundary region need to remove the protective layer, so that the encapsulated boundary region only has a substrate, easy to cut.

In some embodiments, in the region where the protective layer is provided, the protective layer has apertures corresponding to the aperture regions. The orthographic projections of the apertures of the protective layer on the substrate overlap with the aperture regions.

In some embodiments, as shown in FIGS. 4 and 5, the protective layer 2023 includes a first protective layer 20231 and a second protective layer 20232 disposed on the side of the first protective layer 20231 facing away from the substrate 1.

The protective layer 2023 includes vent holes 13 through the thickness of the first protective layer 20231 as well as the second protective layer 20232.

The orthographic projection of the vent hole on the substrate 1 falls into the island region 103, and the orthographic projection of the vent hole on the substrate 1 does not overlap with the orthographic projection of the anode layer on the substrate 1.

In some embodiments, both the display region and the peripheral region, the protective layer needs to be provided with vent holes. In the display region, the orthographic projections of vent holes on the substrate projection and the orthographic projection of the anode on the substrate do not overlap with each other. In the peripheral region, the orthographic projections of the vent holes on the substrate may overlap with the orthographic projection of the conductive layer included in the peripheral driving circuit on the substrate. The pattern of the vent holes in the peripheral region may be the same as the pattern of the vent holes in the display region.

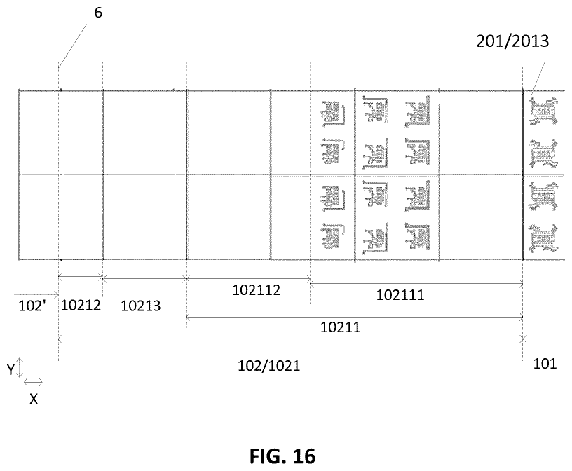

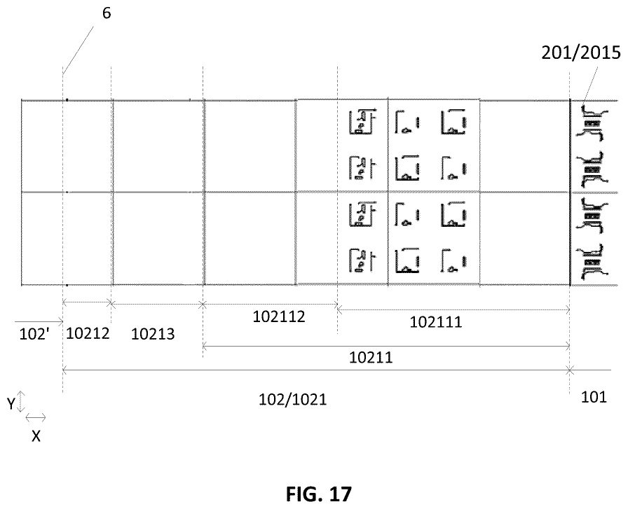

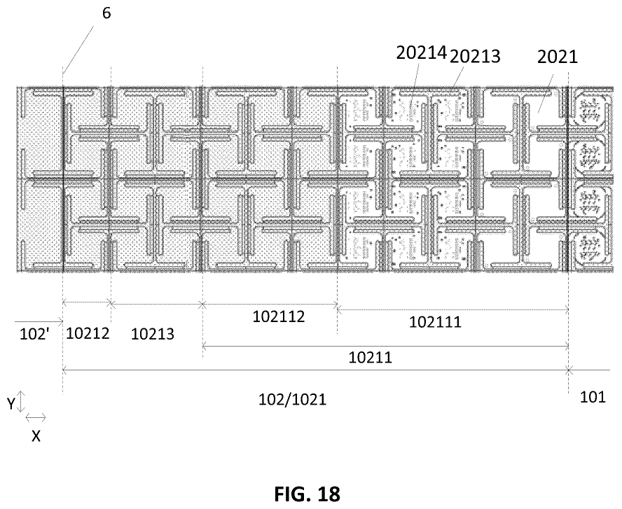

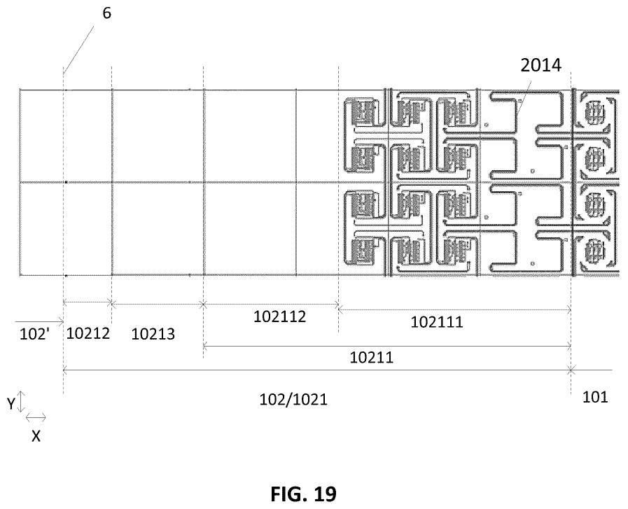

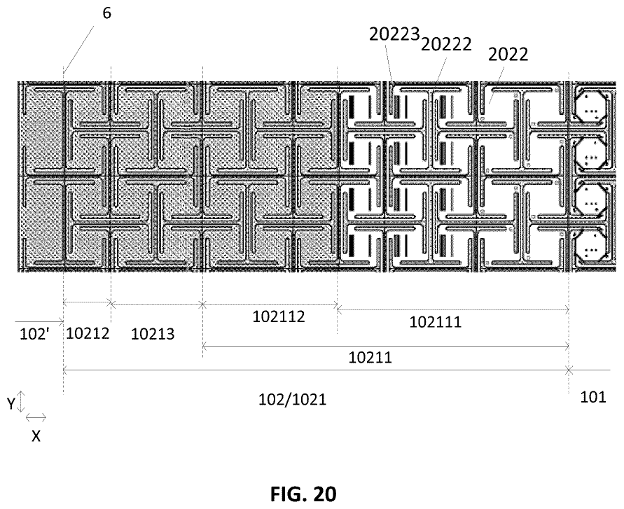

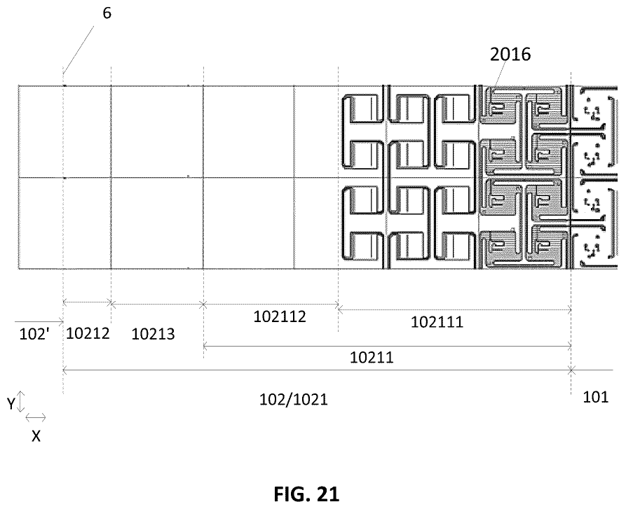

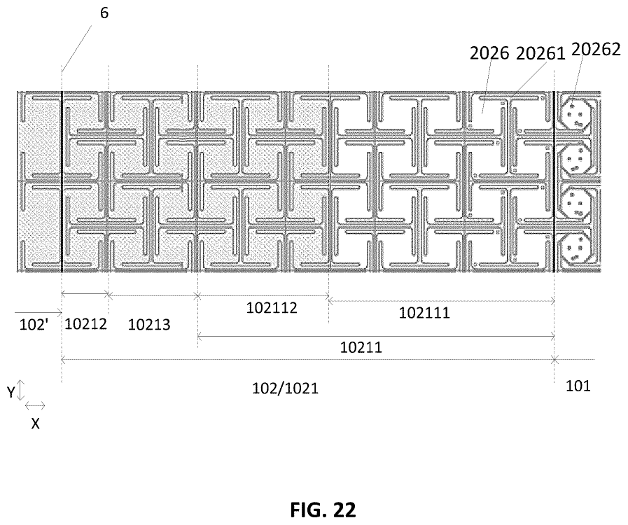

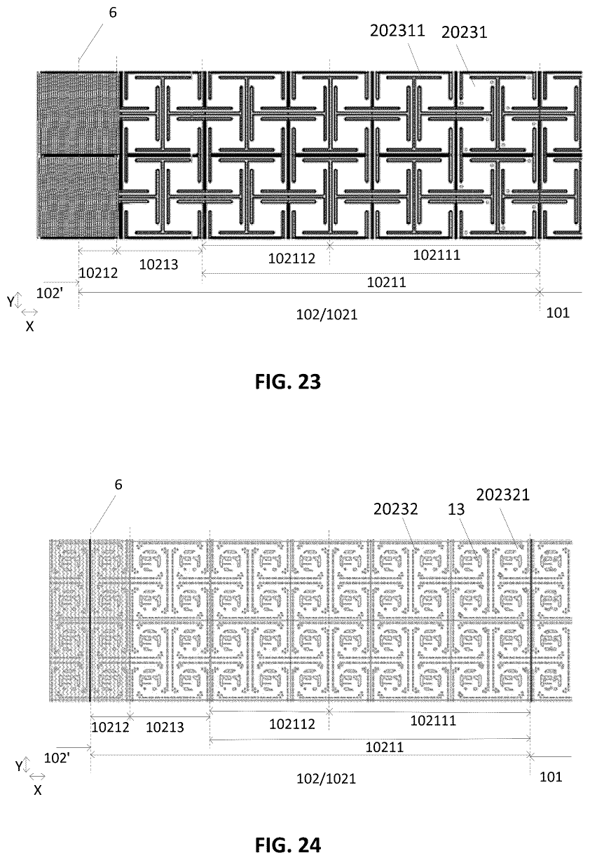

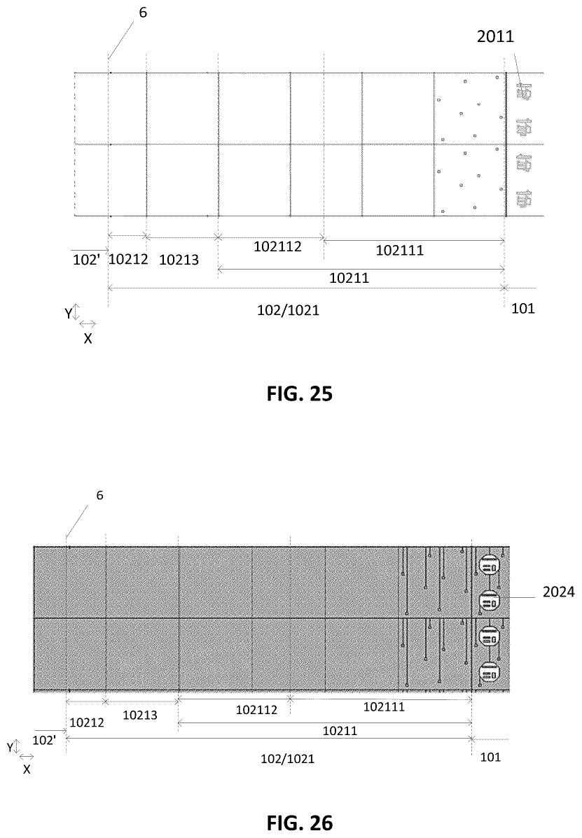

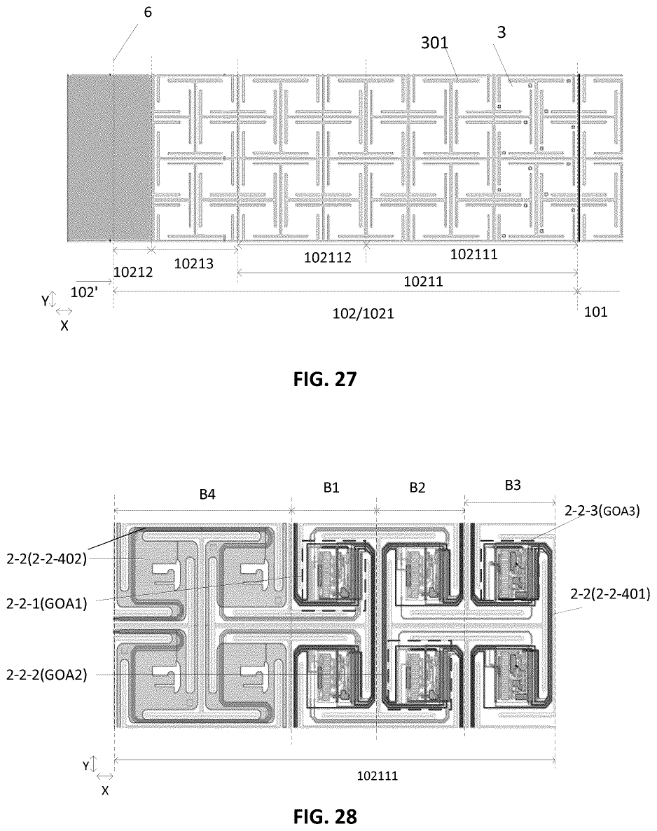

Next, the manufacturing process of the AMOLED display panel and the patterns of some film layers provided by embodiments of the present disclosure are introduced with examples.
1. Form a buffer layer on a flexible substrate.
2. Form a pattern of the active layer on the side of the buffer layer facing away from the flexible substrate, the pattern of the active layer 12 is shown in FIG. 15, and the active layer 12 is located in the display region 101 as well as the circuit region 102111.
3. Form a pattern of a first gate insulating layer on the side of the active layer facing away from the flexible substrate, the first gate insulating layer is located in the display region as well as in the island region and the bridge region of the circuit region, and the first gate insulating layer has an aperture in the region corresponding to the aperture region.
4. Form a pattern of a first conductive layer on the side of the first gate insulating layer facing away from the flexible substrate; the pattern of the first conductive layer 2013 is shown in FIG. 16, and the first conductive layer 2013 is located in the display region 101 as well as in the circuit region 102111.
5. Form a pattern of a second gate insulating layer on the side of the first conductive layer facing away from the flexible substrate, the second gate insulating layer is located in the display region as well as in the island and bridge regions of the circuit region, and the second gate insulating layer has an aperture in the region corresponding to the aperture region.
6. As shown in FIG. 17, form a pattern of a third conductive layer 2015 on the side of the second gate insulating layer facing away from the flexible substrate, and the pattern of the third conductive layer 2015 is disposed in the display region 101 as well as in the circuit region 102111.
7. As shown in FIG. 18, form a pattern of a first interlayer insulating layer 2021 on the side of the third conductive layer facing away from the flexible substrate. The first interlayer insulating layer 2021 is located in the display region 101 and the circuit region 102111, the first interlayer insulating layer 2021 in the region corresponding to the aperture region has the sixth aperture 20213, the first interlayer insulating layer 2021 also has a third aperture 20214, the third aperture 20214 is used to realize the electrical connection between the conductive layers. It should be noted that the white region in FIG. 18 is the region reserved for the first interlayer insulating layer.
8. As shown in FIG. 19, form a pattern of a second conductive layer 2014 on the side of the first interlayer insulating layer facing away from the flexible substrate, and the pattern of the second conductive layer 2014 is disposed in the display region 101 as well as in the circuit region 102111.
9. As shown in FIG. 20, form a pattern of a first planarization layer 2022 on the side of the second conductive layer facing away from the flexible substrate. The first planarization layer 2022 is located in the display region 101 as well as the circuit region 102111, the first planarization layer 2022 has a second aperture 20222 in the region corresponding to the aperture region, the first planarization layer 2022 also has a fourth aperture 20223 through the thickness of the conductive layer used to realize the electrical connection between the conductive layers. It should be noted that the white region in FIG. 20 is the region retained by the first planarization layer.
10. As shown in FIG. 21, form a pattern of the fourth conductive layer 2016 on the side of the first planarization layer facing away from the flexible substrate. The pattern of the fourth conductive layer 2016 is located in the display region 101 as well as in the circuit region 102111.
11. As shown in FIG. 22, form a pattern of a second planarization layer 2026 on the side of the fourth conductive layer facing away from the flexible substrate. The second planarization layer 2026 is located in the display region 101 as well as the circuit region 102111, the second planarization layer 2026 has a seventh aperture 20261 in the region corresponding to the aperture region, the second planarization layer 2026 also has a fifth aperture 20262 through the thickness of the conductive layer for the realization of the electrical connection between the conductive layers. It should be noted that the white region in FIG. 22 is the region retained by the second planarization layer.
12. Form a pattern of the first protective layer on the side of the second planarization layer facing away from the flexible substrate, and the pattern of the first protective layer 20231 is shown in FIG. 23, and the pattern of the first protective layer 20231 is located in the display region 101, the encapsulated coverage region 10211, and the encapsulated boundary region 10213. That is, after the formation of the first protective layer 20231, the patterning process removes the first protective layer 20231 in the aperture region of the display region 101, the aperture region of the encapsulated coverage region 10211, the aperture region of the encapsulated boundary region 10213, and the cutting boundary region 10212. In the aperture region of the display region 101, the aperture region of the encapsulated coverage region 10211, the aperture region of the encapsulated boundary region 10213, the first protective layer 20231 has the third apertures 202311 that correspond to the aperture region. It should be noted that after the formation of the first protective layer, no venting holes are formed in the first protective layer for the time being. The white region in FIG. 23 is the region reserved for the first protective layer.
13. Form the pattern of the second protective layer on the side of the first protective layer facing away from the flexible substrate and form the pattern of the vent hole 13. The pattern of the second protective layer 20232 is shown in FIG. 24, and the second protective layer 20232 is located in the display region 101, the encapsulated coverage region 10211, and the encapsulated boundary region 10213. That is, after the formation of the second protective layer 20232, the pattern process removes the second protective layer 20232 from the aperture region of the display region 101, the aperture region of the encapsulated coverage region 10211, the aperture region of the encapsulated boundary region 10213, and the cutting boundary region 10212. The second protective layer 20232 also has a fourth aperture 202321 corresponding to the aperture region. It is to be noted that a pattern of the vent holes 13 that penetrate through the second protective layer as well as the first protective layer is formed in this step. The white region in FIG. 24 is the region retained by the second protective layer.
14. As shown in FIG. 25, form a pattern of anode layer 2011. The anode layer 2011 is only located in the island region of the display region 101.
15. Form a pattern of the pixel definition layer. The pattern of the pixel definition layer 2024 is shown in FIG. 26. The pixel definition layer 2024 is located only in the island region of the display region 101. That is, after the pixel definition layer is formed, the pixel definition layer is removed by a patterning process from the opening region, the first peripheral region, and the aperture region and the bridge region of the display region. The white region in FIG. 26 is the region retained by the pixel definition layer 2024.
16. Form a pattern of the light-emitting functional layer and a pattern of the cathode.
17. Form a pattern of the encapsulation layer. The pattern of the encapsulation layer 3 is shown in FIG. 27, the encapsulation layer 3 is located in the display region 101 and the encapsulation coverage region 10211, after the encapsulation layer 3 is formed, the encapsulation layer 3 is removed from the aperture region of the display region 101, the aperture region of the encapsulation coverage region 10211, the encapsulated boundary region 10213, and the cutting boundary region 10212, and the encapsulation layer 3 has the fifth corresponding to the aperture region. The white region in FIG. 27 is the region retained by the encapsulation layer 3.
18. Form patterns of aperture regions on the flexible substrate as well as on the buffer layer.

In some embodiments, as shown in FIG. 28, the peripheral signal lines 2-2-4 include: a plurality of connecting signal lines 2-2-401.

Two adjacent peripheral driving units GOA in the second direction Y are electrically connected by the connecting signal line 2-2-401; the second direction Y intersects with the first direction X; in the embodiment of the present disclosure, the second direction Y and the first direction X is vertical as an example to illustrate.

The orthographic projection of the peripheral driving unit GOA on the substrate falls into the island region 103, and the orthographic projection of the connecting signal line 2-2-401 on the substrate passes through the bridge region 105 and extends to the island region 103.

In some embodiments, as shown in FIG. 28, the plurality of peripheral signal lines 2-2-4 further include: a plurality of peripheral driving signal lines 2-2-402.

In some embodiments, in the display region, the plurality of pixel driving units are divided into a plurality of rows of pixel driving units extending in the first direction X and arranged in the second direction Y.

The plurality of peripheral driving signal lines are electrically connected with the rows of pixel driving units and the peripheral driving unit GOA.

In some embodiments, the plurality of connecting signal lines are located in at least one layer of: the first conductive layer, the second conductive layer, the third conductive layer, or the fourth conductive layer. The plurality of peripheral driving signal lines are located in at least one layer of: the first conductive layer, the second conductive layer, the third conductive layer, or the fourth conductive layer.

In some embodiments, as shown in FIG. 28, the circuit region 102111 includes: a first circuit region B1, a second circuit region B2, a third circuit region B3, and a signal line region B4. In the first direction X, the first circuit region B1 is located between the signal line region B4 and the second circuit region B2, and the third circuit region B3 is located on the side of the second circuit region B2 away from the first circuit region B1. The first circuit region B1 includes the first peripheral driving circuit 2-2-1, the second circuit region B2 includes the second peripheral driving circuit 2-2-2, the third circuit region B3 includes the third peripheral driving circuit 2-2-3. The plurality of peripheral driving signal lines 2-2-402 are electrically connected with the row of pixel driving units (not shown) passing through the signal line region B4. The first peripheral driving circuit 2-2-1 includes the first peripheral driving unit GOA1, and the second peripheral driving circuit 2-2-2 includes the second peripheral driving unit GOA2, and the third peripheral driving circuit 2-2-3 includes the third peripheral driving unit GOA3.

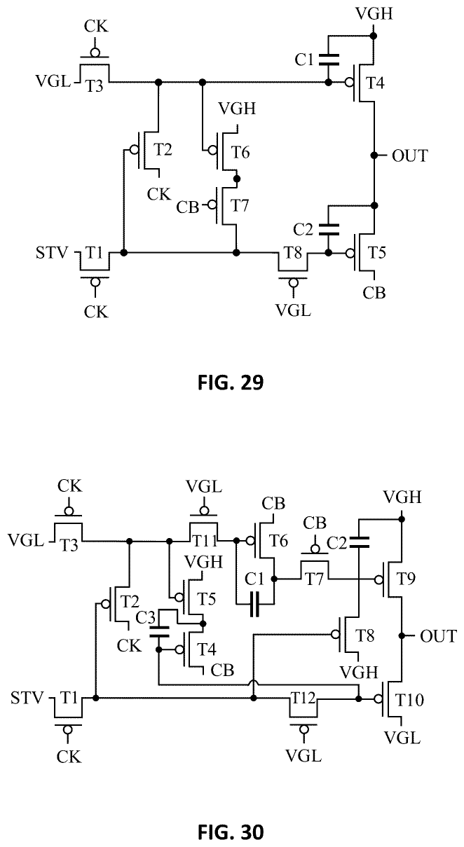

In some embodiments, the driving unit of the first peripheral driving circuit and the driving unit of the second peripheral driving circuit have the same composition. The driving unit of the first peripheral driving circuit and the driving unit of the second peripheral driving circuit are as shown in FIG. 29, including: a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, an eighth thin-film transistor T8, a first capacitor C1, and a second capacitor C2.

In some embodiments, the driving unit of the third peripheral driving circuit is shown in FIG. 30, and includes a first thin-film transistor T1, a second thin-film transistor T2, a third thin-film transistor T3, a fourth thin-film transistor T4, and a fifth thin-film transistor T5, the sixth thin-film transistor T6, the seventh thin-film transistor T7, the eighth thin-film transistor T8, the ninth thin-film transistor T9, the tenth thin-film transistor T10, the first capacitor C1, the second capacitor C2, and the third capacitor C3.

In some embodiments, the plurality of connecting signal lines include, for example, a high level power line, a low level power line, an output signal line, a frame start signal line, a clock signal line, and a low level signal line.

In some embodiments, for the driving unit as shown in FIG. 29, the high-level power line VGH is electrically connected with the source electrode of the sixth thin-film transistor T6, the source electrode of the fourth thin-film transistor T4, and the first electrode of the first capacitor C1. The low-level power line VGL is electrically connected with the source electrode of the third thin-film transistor T3 and the gate electrode of the eighth thin-film transistor T8. The frame start signal line STV is electrically connected with the source electrode of the first thin-film transistor T1. The clock signal line CK is electrically connected with the gate electrode of the first thin-film transistor T1, the source electrode of the second thin-film transistor T2, and the gate electrode of the third thin-film transistor T3. The low-level signal line CB is connected with the gate electrode of the seventh thin-film transistor T7 and the source electrode of the transistor T5. The output signal line VOUT is electrically connected with the drain electrode of the fourth thin-film transistor T4, the drain electrode of the fifth thin-film transistor T5, and the first electrode of the second capacitor C2.

In some embodiments, for the driving unit as shown in FIG. 30, the high-level power line VGH is connected with the source electrode of the fifth thin-film transistor T5, the source electrode of the eighth thin-film transistor T8, the source electrode of the ninth thin-film transistor T9 and the first electrode of the second capacitor C2. The low-level power line VGL and the source electrode of the third thin-film transistor T3, the source electrode of the tenth thin-film transistor T10, the gate electrode of the eleventh thin-film transistor T11, and the e gate electrode of the transistor T12. The frame start signal line STV is electrically connected with the source electrode of the first thin-film transistor T1. The clock signal line CK is connected with the gate electrode of the first thin-film transistor T1, the source electrode of the second thin-film transistor T2, and the gate electrode of the three thin-film transistors T3. The low-level signal line CB is electrically connected with the gate electrode of the seventh thin-film transistor T7, the source electrode of the fourth thin-film transistor T4, and the source electrode of the sixth thin-film transistor T6. The output signal line VOUT is electrically connected with the drain electrode of the ninth thin-film transistor T9, and the drain electrode of the tenth thin-film transistor T10.

It should be noted that, in the driving unit as shown in FIG. 29, the signal output by the output signal line VOUT is used as the scanning signal or reset signal of the pixel driving unit. Correspondingly, the peripheral driving signal line electrically connected with the output signal line VOUT is scanning signal line or reset signal line that transmits scanning signals. In the driving unit shown in FIG. 30, the signal output by the output signal line VOUT is used as the light-emitting control signal of the pixel driving unit. Correspondingly, the peripheral driving signal line electrically connected with the output signal line VOUT is the light-emitting control signal line that transmits the light-emitting control signal.

In some embodiments, the peripheral driving circuit may include a plurality of peripheral driving signal lines, and the plurality of peripheral driving signal lines include a high level power line and a low level power line.

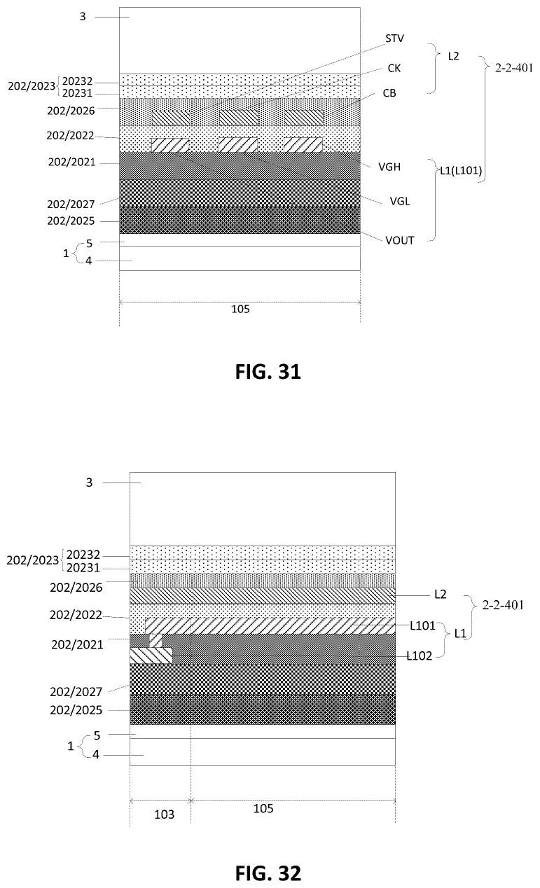

In some embodiments, as shown in FIGS. 31 and 32, the multiple connecting signal lines 2-2-401 include: a first signal line L1, and a second signal line L2 located in a different conductive layer from the first signal line L1.

Embodiments of the present disclosure provide a display panel in which a plurality of connecting signal lines are located in different layers, thereby avoiding the limitation of the line width of the connecting signal lines by the space limitation of the bridge region, and avoiding the increase in impedance caused by the line width of the connecting signal lines being too narrow.

In some embodiments, as shown in FIGS. 31 and 32, at least part of the first signal line L1 includes a first portion L101 and a second portion L102 located in a different conductive layer from the first portion L101 and electrically connected with the first portion L101. The second conductive layer 2014 includes a first portion L101. The first conductive layer 2013 includes a second portion L102. The orthographic projection of the first part L101 on the substrate 1 passes through the bridge region 105 and extends to the island region 103. The orthographic projection of the second portion L102 on the substrate falls into the island region 103.

The fourth conductive layer 2016 includes the second signal line L2.

In some embodiments, as shown in FIGS. 31 and 32, the high-level power line VGH, the low-level power line VGL, and the output signal line VOUT are the first signal line L1, the frame start signal line STV, and the clock signal line CK and low-level signal line CB are the second signal line L2.

It should be noted that FIG. 31 shows a cross-sectional view perpendicular to the direction of extension of the connecting signal line, and FIG. 32 shows a cross-sectional view along the direction of extension of the connecting signal line.

In some embodiments, as shown in FIG. 31, in the bridge region 105, the orthographic projection of the first signal line L1 on the substrate 1 and the orthographic projection of the second signal line L2 on the substrate 1 have an overlapping region. Specifically, in order to avoid increasing the width of the bridge region, in the bridge region 105, the orthographic projection of the first signal line L1 on the substrate 1 overlaps with the orthographic projection of the second signal line L2 on the substrate 1.

For the first signal line including the first portion and the second portion, in some embodiments, as shown in FIG. 31, in the bridge region 105, the orthographic projection of the first portion L101 on the substrate 1 and the second signal line L2 on the substrate 1 have an overlapping region. Specifically, in order to avoid increasing the width of the bridge region, in the bridge region 105, the orthographic projection of the first portion L101 on the substrate 1 overlaps with the orthographic projection of the second signal line L2 on the substrate 1.

In some embodiments, in the same conductive layer, the line width of the connecting signal line is 3 micrometers, and the distance between two adjacent connecting signal lines is 2.5 micrometers.

Alternatively, if there is sufficient wiring space in the bridge region in the direction perpendicular to the extension of the connecting signal lines, in some embodiments, in the bridge region, the orthographic projection of the first portion on the substrate and the orthographic projection of the second signal line on the substrate do not overlap with each other. Thereby, parasitic capacitance between the connecting signal lines of different layers can be reduced.

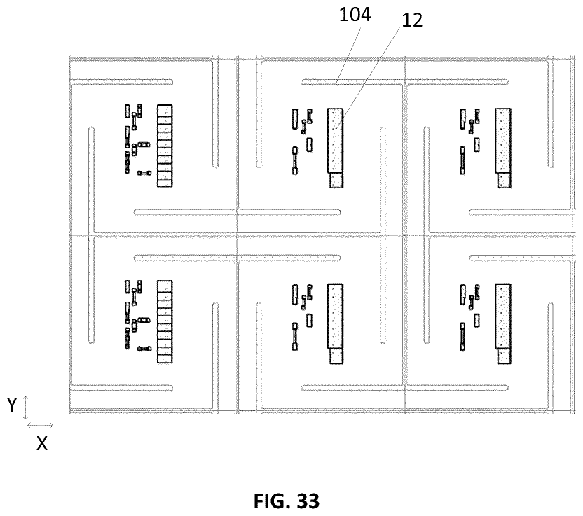

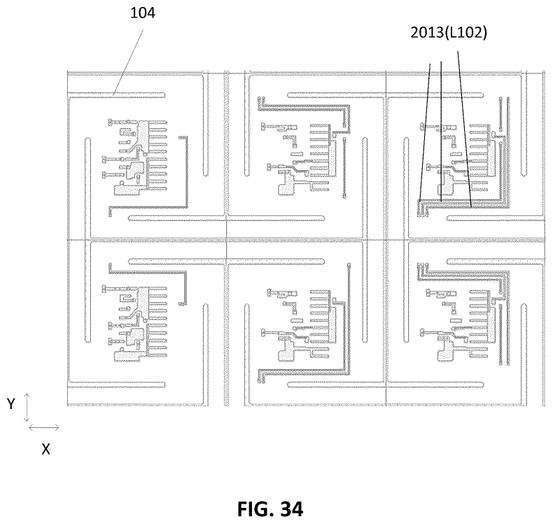

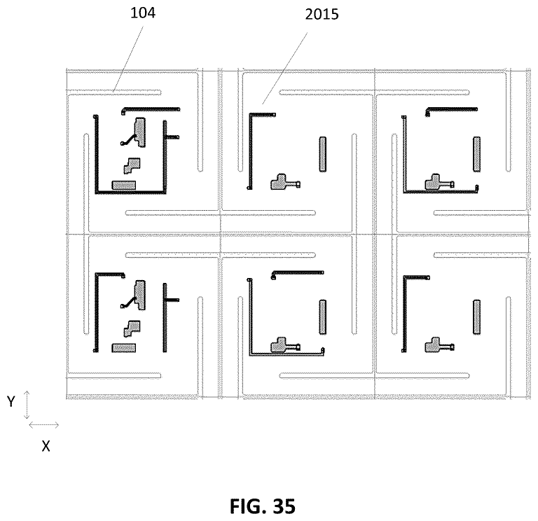

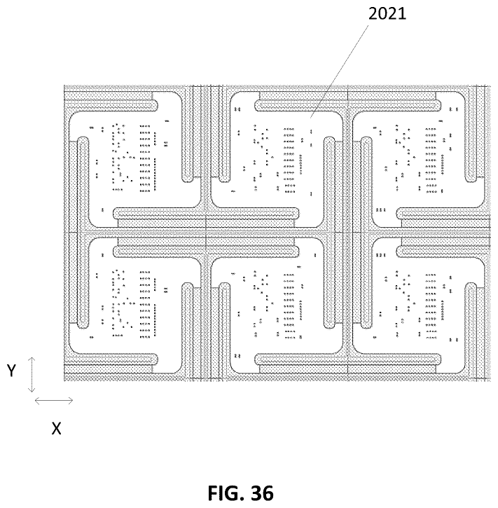

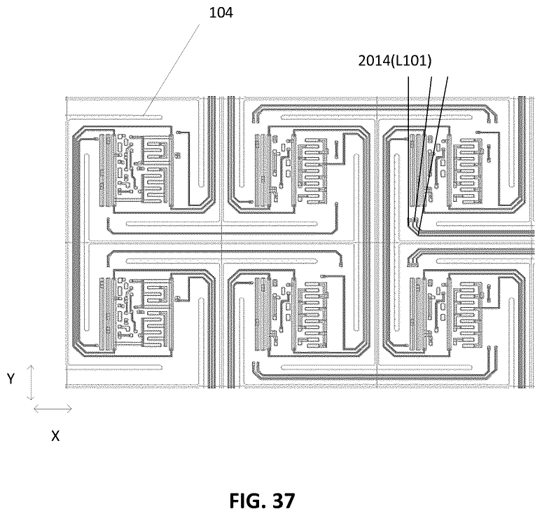

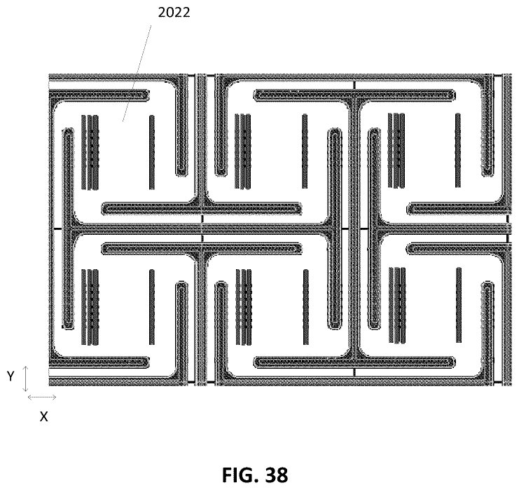

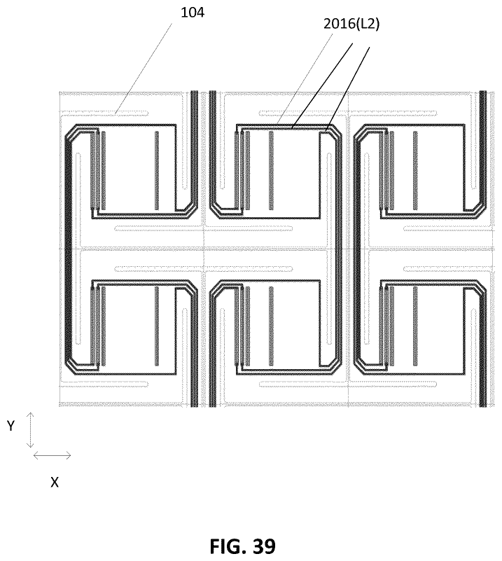

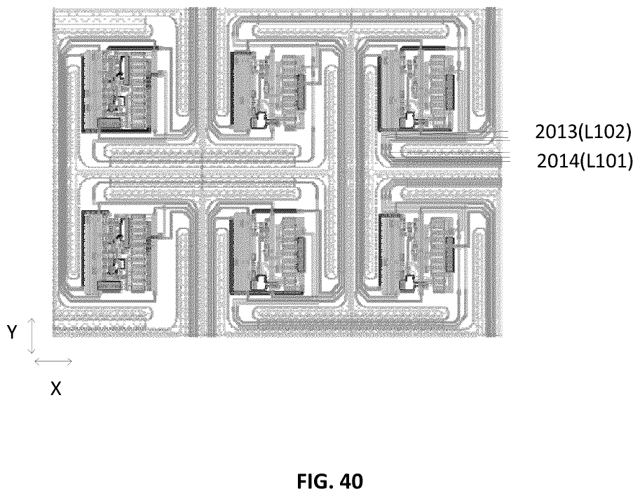

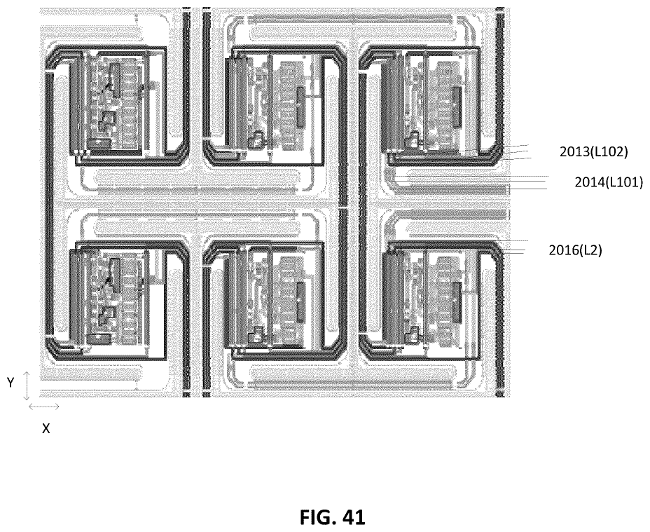

In some embodiments, when the plurality of connecting signal lines includes a first signal line and a second signal line, the patterns of the active layer 12, the first conductive layer 2013, the third conductive layer 2015, the first interlayer insulating layer 2021, the second conductive layer 2014, the first planarization layer 2022, and the fourth conductive layer 2016 are shown in FIGS. 33 to 39, respectively, and the pattern of FIGS. 33 to 37 after stacking is shown in FIG. 40, and the pattern of FIGS. 33 to 39 after stacking is shown in FIG. 41.

In some embodiments, as shown in FIG. 1, the plurality of island regions 103 included in the display region 101 is divided into a plurality of rows of first island regions 8 extending in the first direction X and arranged in the second direction Y.

The plurality of island regions 103 included in the first peripheral region 1021 are divided into a plurality of rows of second island regions 7 extending in the first direction X and arranged in the second direction Y.

One row of second island regions 7 corresponds to n rows of first island regions 8, where n is an integer greater than or equal to 1.

It should be noted that in FIG. 1, n is equal to 1 as an example for illustration.

When the display panel is an AMOLED display panel, in some embodiments, the row of second island regions includes at least one peripheral driving unit.

The row of first island regions includes at least one row of pixel driving units.

The peripheral driving units included in one row of second island regions are electrically connected with the rows of pixel driving units included in n rows of first island regions.

It should be noted that in the first direction, both sides of the display region are peripheral regions, and the peripheral driving circuit may be provided in only one of the peripheral regions or in both peripheral regions of the display region. If the peripheral driving circuits are provided on both sides of the display region, for example, the peripheral driving circuits on both sides of the display region alternately drive pixels located in different rows of the first island regions.

In some embodiments, as shown in FIG. 1, in at least part of the peripheral region 102, the pattern of at least part of the aperture region 104 is an I-shaped. That is, the pattern of the partially aperture region includes one first bar portion and two second bar portions, the first bar portion is perpendicular to the extension direction of the second bar portion, the two second bar portions is located at opposite ends of the extension direction of the first bar portion, and a straight line where the first bar portion is located divides the second bar portion equally.

It should be noted that in the peripheral region, there are also aperture regions where the I-shaped pattern cannot be completely arranged, and the pattern of these aperture regions is part of the I-shaped.

It should be noted that the embodiments shown in FIGS. 1 to 41 are exemplified by part of the pattern of the aperture region as an example of an I-shaped. Of course, the pattern of the aperture region can also be other shapes. When the pattern of the aperture region changes, the pattern of the bridge region will also change, accordingly, the pattern of the conductive layer in the bridge region will change, but the electrical connection relationship between the conductive layer of the bridge region and the conductive layer of the island region can remain unchanged. The specific film layer configuration of the peripheral signal line in the bridge region can also remain unchanged. For example, regardless of the bridge region of the shape of how to change, can be set up as shown in FIGS. 31 and 32, the multiple connecting signal lines are located in different layers. When the pattern of the aperture region changes, the shape of the island region may or may not change.

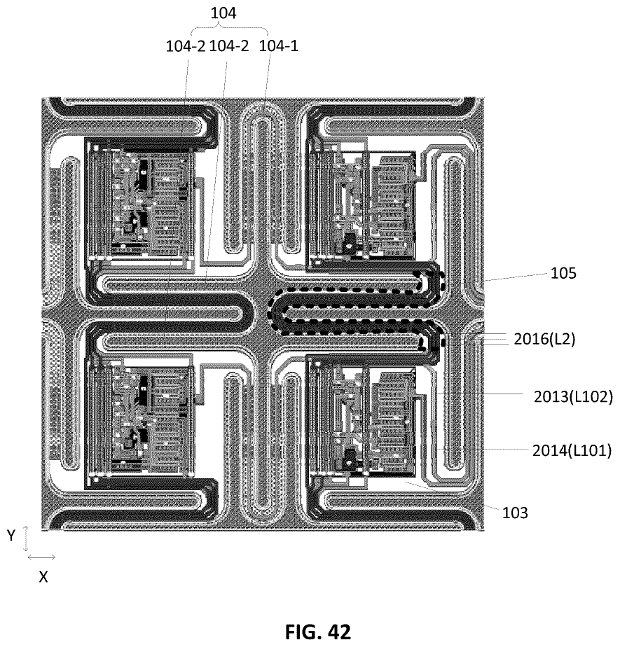

Alternatively, in some embodiments, in at least part of the peripheral region, as shown in FIG. 42, an orthographic projection of a pattern of at least part of the aperture region 104 on the substrate 1 includes a third portion 104-1 and two fourth portions 104-2; an extension direction of the third portion 104-1 is different from an extension direction of the fourth portion 104-2, and the third portion 104-1 passes through the two fourth portions 104-2.

Embodiments of the present disclosure provide a display panel in which a pattern of an aperture region includes the third portion and the fourth portion, and the third portion passes through the two fourth portions, and for adjacent aperture regions, the third portion of one of the aperture regions extends to a region between two fourth portions of the other aperture region, and the region between the third portion of one of the aperture regions and the two fourth portions of the other aperture region is a bridge region. Compared to an I-shaped, the total extension length of the bridge region can be increased, thereby increasing the stretchable capability of the bridge region and increasing the stretchable capability of the peripheral region.

In some embodiments, in the peripheral region, there will also be aperture regions that cannot be completely set up to include the patterns of the third portion and the fourth portion, and the patterns of these aperture regions are a part of the patterns that include the third portion and the fourth portion.

In some embodiments, the pattern of at least part of the aperture region included in the peripheral region is the same as the pattern of at least part of the aperture region included in the display region.

For example, as shown in FIG. 1, the shapes of the aperture regions 104 included in both the display region 101 and the peripheral region 102 are an I-shaped or a part of an I-shaped.

Of course, when at least part of the aperture region pattern included in the peripheral region includes the third portion and the fourth portion, at least part of the aperture region pattern included in the display region also includes the third portion and the fourth portion.

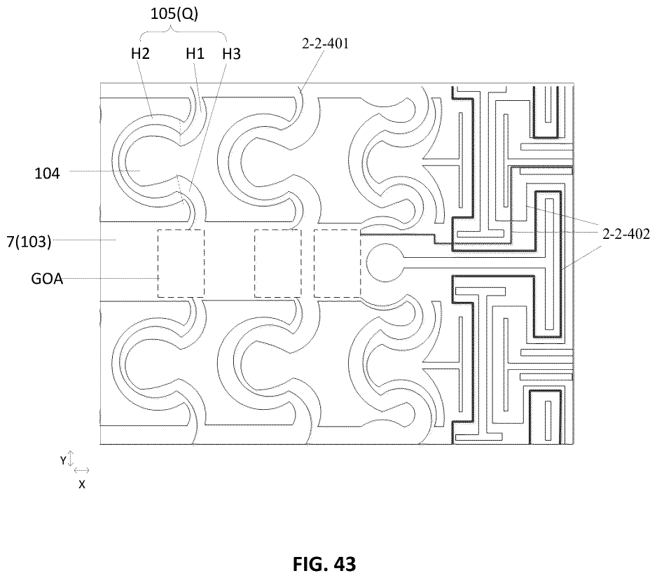

In some embodiments, as shown in FIG. 43, in at least part of the peripheral region 102, the bridge region 105 and the aperture region 104 are connected with the row of second island regions 7 in the second direction Y.

The bridge region 105 includes a curved portion Q, the orthographic projection of the curved portion Q on the substrate 1 curves and extends in the second direction Y, and the aperture region 104 is located between two adjacent bridge regions 105 in the first direction X.

The display panel provided by embodiments of the present disclosure, the bridge region includes a curved portion, i.e., the pattern of the bridge region is curved, and compared to the I-shaped aperture region, the bridge region has most of the strip-shaped extension region, the curved bridge region can increase the total extension length of the bridge region, thereby improving the stretchable capability of the bridge region and the stretchable capacity of the peripheral region.

In some embodiments, as shown in FIG. 43, the curve portion Q includes a plurality of arcuate portions H connected in sequence. In FIG. 43, the curve portion Q includes three arcuate portions H1, H2, and H3 as an example. The convex directions of the arcuate portions of H1 and H3 are consistent, and the convex directions of the arcuate portions of H1 and H3 are opposite with the convex direction of the arcuate portions of H2.

In some embodiments, as shown in FIG. 43, in the region corresponding to the peripheral driving unit GOA, the bridge region include the curved portion, while in the peripheral region corresponding to the peripheral driving signal line 2-2-402, the pattern shape of the aperture region is I-shaped or part of I-shaped. The bridge region has most of the strip extending region.

Of course, in some embodiments, the peripheral region corresponding to the peripheral driving signal line, at least part of the pattern of the aperture region consists of the third portion and the fourth portion, i.e., the pattern of the aperture region is shown in FIG. 42.

It should be noted that, as shown in FIG. 43, in the region corresponding to the peripheral driving unit GOA, the island region 103 included in the row of second island regions 7 are integrally connected.

In some embodiments, when a portion of the bridge region of the peripheral region includes the curved portion, an orthographic projection of a pattern of at least part of the aperture region comprised in the display region on the substrate is different from an orthographic projection of a pattern of at least part of the aperture region comprised in the peripheral region on the substrate.

In some embodiments, when a portion of the bridge regions in the peripheral region includes the curved portion, the pattern of at least part of the aperture region included in the display region is an I-shaped. Alternatively, in some embodiments, the pattern of at least part of the aperture region included in the display region includes the third portion and the fourth portion, i.e., the pattern of the aperture region is as shown in FIG. 42.

In some embodiments, when a portion of the bridge region of the peripheral region includes the curved portion, for example, in a first direction, both sides of the display region are first peripheral regions, i.e., peripheral driving circuits are provided in the peripheral regions on both sides of the display region, and the peripheral driving circuits on both sides of the display region alternately drive pixels in the rows of first island regions.

A display device provided by embodiments of the present disclosure, including the display panel provided by embodiments of the present disclosure.

The display device provided in embodiments of the present disclosure is any product or component with display function, such as a mobile phone, tablet computer, television, monitor, laptop, digital photo frame, navigation device, etc. The other essential components of the display device should be understood by those skilled in the art and should not be repeated here, nor should they be used as limitations on this disclosure. The implementation of the display device can refer to the above embodiments of the display panel, and the repetition will not be repeated.

In summary, embodiments of the present disclosure provide a display panel that can be applied to a stretchable display product, the display region includes the island region, the bridge region, and the aperture region, and the bridge region is deformed by a force, so that the display region can realize a stretching function. Moreover, at least part of the peripheral region surrounding the display region also includes the island region, the bridge region, and the aperture region, so that the peripheral region can also realize the stretching function. Furthermore, when the peripheral driving circuit is provided in the peripheral region including the aperture region, the orthographic projection of the peripheral driving circuit on the substrate and the aperture region do not overlap with each other, and the number of insulating layers of the peripheral driving circuit is less than the number of insulating layers of pixel circuits in the display region, which is more favorable to improving the stretching performance of the peripheral region.

Although preferred embodiments of the present disclosure have been described, additional changes and modifications can be made to these embodiments once the basic inventive concepts are known to those skilled in the art. Therefore, the appended claims are intended to be construed as including the preferred embodiments and all changes and modifications falling within the scope of the present invention.

Obviously, those skilled in the art can make various changes and variations to the present disclosure without departing from the spirit and scope of the present disclosure. Thus, if such modifications and variations of the present disclosure fall within the scope of the present claims and their technical equivalents, the present disclosure is intended to include such modifications and variations.

1.-26. (canceled)

27. A display panel, comprising:
a substrate, wherein the substrate comprises: a display region, a peripheral region surrounding the display region; the display region and at least part of the peripheral region comprise: a plurality of island regions arranged in an array, an aperture region between adjacent island regions, and a bridge region connecting adjacent island regions;
a circuit layer on a side of the substrate, wherein the circuit layer comprises a plurality of insulating layers and a plurality of conductive layers;
wherein the circuit layer is divided into a plurality of pixel circuits in the display region and a plurality of peripheral driving circuits at least in the peripheral region;
orthographic projections of conductive layers and insulating layers comprised in the peripheral driving circuit on the substrate overlap with the island region and the bridge region;
the orthographic projections of the conductive layers and the insulating layers comprised in the peripheral driving circuit on the substrate do not overlap with the aperture region;
a number of the insulating layers comprised in the peripheral driving circuit is less than a number of insulating layers comprised in the pixel circuit.

28. The display panel according to claim 27, wherein the pixel circuit comprises:
a pixel driving circuit and a light-emitting device on a side of the pixel driving circuit facing away from the substrate;
the plurality of conductive layers comprises: an anode layer and a cathode layer on a side of the anode layer facing away from the substrate;
the anode layer comprises an anode of the light-emitting device, and the cathode layer comprises a cathode of the light-emitting device;
orthographic projections of the anode layer and the cathode layer on the substrate do not overlap with the peripheral region comprising the aperture region.

29. The display panel according to claim 28, further comprising: an encapsulation layer on a side of the light-emitting device facing away from the substrate;
wherein an orthographic projection of the encapsulation layer on the substrate does not overlap with the aperture region;
the peripheral region comprises a first peripheral region adjacent to the display region in a first direction;
the first peripheral region comprises: an encapsulated coverage region adjacent to the display region, a cutting boundary region on a side of the encapsulated coverage region away from the display region in the first direction, and an encapsulated boundary region between the encapsulated coverage region and the cutting boundary region;
an orthographic projection of the encapsulation layer on the substrate does not overlap with the cutting boundary region and the encapsulated boundary region, and the orthographic projection of the encapsulation layer on the substrate covers the island regions and the bridge regions in the display region and the island regions and the bridge regions in the encapsulated coverage region;
the encapsulated coverage region comprises: a circuit region adjacent to the display region, and a non-circuit region between the circuit region and the encapsulated boundary region; orthographic projections of the conductive layers comprised in the peripheral driving circuit on the substrate fall into the circuit region.

30. The display panel according to claim 29, wherein the plurality of conductive layers further comprise: a first conductive layer between the substrate and the anode layer, and a second conductive layer between the first conductive layer and the anode layer;
the pixel driving circuit comprises: a first level signal line electrically connected with the anode;
the peripheral driving circuit comprises: a second level signal line electrically connected with the cathode;
the first conductive layer comprises the first level signal line, and the second conductive layer comprises the second level signal line.

31. The display panel according to claim 30, wherein the plurality of insulating layers comprise: a first interlayer insulating layer between the first conductive layer and the second conductive layer, and a first planarization layer between the second conductive layer and the anode layer;
an orthographic projection of the first interlayer insulating layer on the substrate does not overlap with the first peripheral region;
an orthographic projection of the first planarization layer on the substrate covers the peripheral driving circuit; and
the orthographic projection of the first planarization layer on the substrate does not overlap with the non-circuit region, the cutting boundary region and the encapsulated boundary region.

32. The display panel according to claim 31, wherein the plurality of insulating layers further comprise: a protective layer between the first planarization layer and the anode layer;
an orthographic projection of the protective layer on the substrate overlaps with the encapsulated coverage region and the encapsulated boundary region, and the orthographic projection of the protective layer on the substrate does not overlap with the cutting boundary region.

33. The display panel according to claim 29, wherein the pixel driving circuit comprises a plurality of pixel driving units;
the peripheral driving circuit comprises: a plurality of peripheral driving units, and a plurality of peripheral signal lines; and
the pixel driving unit and the peripheral driving unit both comprise a thin-film transistor and a capacitor.

34. The display panel according to claim 33, wherein the plurality of conductive layers further comprise: a first conductive layer, and a second conductive layer between the first conductive layer and the anode layer; the first conductive layer comprises: a gate of a thin-film transistor of the pixel driving unit and a gate of a thin-film transistor of the peripheral driving unit; the second conductive layer comprises: a source electrode and a drain electrode of the thin-film transistor of the pixel driving unit and a source electrode and a drain electrode of the thin-film transistor of the peripheral driving unit;
the circuit layer further comprises: an active layer of the thin-film transistor; the active layer is between the first conductive layer and the substrate;
the plurality of insulating layers comprise: a first gate insulating layer between the active layer and the first conductive layer, a first interlayer insulating layer between the first conductive layer and the second conductive layer, and a first planarization layer between the second conductive layer and the anode;
orthographic projections of the first gate insulating layer, the first interlayer insulating layer, and the first planarization layer on the substrate cover the peripheral driving circuit, and the orthographic projections of the first gate insulating layer, the first interlayer insulating layer, and the first planarization layer on the substrate do not overlap with the non-circuit region, the cutting boundary region, and the encapsulated boundary region.

35. The display panel according to claim 34, wherein the plurality of insulating layers further comprise: a protective layer between the first planarization layer and the anode layer;
an orthographic projection of the protective layer on the substrate overlaps with the encapsulated coverage region and the encapsulated boundary region, and the orthographic projection of the protective layer on the substrate does not overlap with the cutting boundary region;
wherein the plurality of conductive layers further comprise: a third conductive layer between the first conductive layer and the first interlayer insulating layer;
the plurality of insulating layers further comprise: a second gate insulating layer between the first conductive layer and the third conductive layer;
an orthographic projection of the second gate insulating layer on the substrate covers the peripheral driving circuit, and the orthographic projection of the second gate insulating layer on the substrate does not overlap with the non-circuit region, the cutting boundary region, and the encapsulated boundary region.

36. The display panel according to claim 35, wherein the plurality of conductive layers further comprise: a fourth conductive layer between the first planarization layer and the protective layer;
the plurality of insulating layers further comprise: a second planarization layer between the fourth conductive layer and the protective layer;
an orthographic projection of the second planarization layer on the substrate covers the peripheral driving circuit; and the orthographic projection of the second planarization layer on the substrate does not overlap with the non-circuit region, the cutting boundary region and the encapsulated boundary region.

37. The display panel according to claim 36, wherein the peripheral signal lines comprise: a plurality of connecting signal lines;
two adjacent peripheral driving units in a second direction are electrically connected by the connecting signal line, the second direction intersects with the first direction;
an orthographic projection of the peripheral driving unit on the substrate falls into the island region, and an orthographic projection of the connecting signal line on the substrate passes through the bridge region and extends to the island region;
the plurality of connecting signal lines comprise: a first signal line and a second signal line wherein the first signal line and the second signal line are located in different conductive layers;
at least part of the first signal line comprises: a first portion and a second portion electrically connected with the first portion; the second conductive layer comprises the first portion, the first conductive layer comprises the second portion, an orthographic projection of the first portion on the substrate passes through the bridge region and extends to the island region, and an orthographic projection of the second portion on the substrate falls into the island region;
the fourth conductive layer comprises the second signal line.

38. The display panel according to claim 37, wherein, in the bridge region, the orthographic projection of the first portion on the substrate and an orthographic projection of the second signal line on the substrate have an overlapping region.

39. The display panel according to claim 36, wherein the plurality of peripheral signal lines comprise: a plurality of peripheral driving signal lines;
in the display region, the plurality of pixel driving units are divided into a plurality of rows of pixel driving units extending in the first direction and arranged in the second direction;
the plurality of peripheral driving signal lines are electrically connected with the rows of pixel driving units and the peripheral driving units;
the plurality of peripheral driving signal lines are located in at least one of: the first conductive layer, the second conductive layer, the third conductive layer, or the fourth conductive layer.

40. The display panel according to claim 29, wherein the plurality of insulating layers further comprise: a pixel defining layer between the anode layer and the cathode layer;
the pixel defining layer comprises a plurality of opening regions, and orthographic projections of the opening regions on the substrate fall into an orthographic projection of the anode on the substrate;
the orthographic projections of the opening regions on the substrate do not overlap the aperture region and the first peripheral region.

41. The display panel according to claim 32, wherein the protective layer comprises a vent hole through a thickness of the protective layer;
an orthographic projection of vent hole on the substrate falls into the island region, and the orthographic projection of vent hole on the substrate does not overlap with an orthographic projection of the anode on the substrate.

42. The display panel according to claim 27, wherein the plurality of island regions comprised in the display region are divided into a plurality of rows of first island regions extending in a first direction and arranged in a second direction;
the plurality of island regions comprised in a first peripheral region are divided into a plurality of rows of second island regions extending in the first direction and arranged in the second direction;
one row of second island regions corresponds to n rows of first island regions, wherein n is an integer greater than or equal to 1.

43. The display panel according to claim 42, wherein, the row of second island regions comprises at least one peripheral driving unit;
the row of first island regions comprises at least one row of pixel driving units;
the peripheral driving units comprised in one row of second island regions are electrically connected with rows of pixel driving units comprised in n rows of first island regions.

44. The display panel according to claim 42, wherein, in at least part of the peripheral region, a pattern of at least part of the aperture region comprises a third portion and two fourth portions; an extension direction of the third portion is different from an extension direction of the fourth portion, and the third portion passes through the two fourth portions; or
wherein, in at least part of the peripheral region, the bridge region and the aperture region are connected with the row of second island regions in the second direction; the bridge region comprises a curved portion curving and extending in the second direction, and the aperture region is between two adjacent bridge regions in the first direction.

45. The display panel according to claim 44, wherein the curved portion comprises a plurality of arcuate portions connected in sequence; or
wherein a pattern of at least part of the aperture region comprised in the display region is different from a pattern of at least part of the aperture region comprised in the peripheral region.

46. A display device, comprising the display panel according to claim 27.
